(19) United States
(12) Patent Application Publication
(10) Pub. No.: US 2024/0006520 A1
(43) Pub. Date: Jan. 4, 2024

(54) SEMICONDUCTOR DEVICE

(71) Applicant: FUJI ELECTRIC CO., LTD., Kanagawa (JP)

(72) Inventor: Tatsuya NAITO, Matsumoto-city (JP)

(21) Appl. No.: 18/469,574

(22) Filed: Sep. 19, 2023

Related U.S. Application Data
(63) Continuation of application No. PCT/JP2022/038340, filed on Oct. 14, 2022.

(30) Foreign Application Priority Data
Oct. 15, 2021 (JP) 2021-169659

(51) Int. Cl. H01L 29/739; H01L 29/861

(52) U.S. Cl. CPC H01L 29/7397; H01L 29/861

(57) ABSTRACT

Provided is a semiconductor device in which each of a transistor portion and a diode portion has one or more trench contact portions provided from an upper surface of a semiconductor substrate in a depth direction of the semiconductor substrate, the transistor portion has a first bottom region of a second conductivity type provided in contact with a bottom of any one of the one or more trench contact portions, the diode portion has a second bottom region of the second conductivity type provided in contact with a bottom of any one of the one or more trench contact portions, and a length of the first bottom region in the extending direction is larger than a length of the second bottom region in the extending direction.

The contents of the following patent application(s) are incorporated herein by reference:

NO. 2021-169659 filed in JP on Oct. 15, 2021

NO. PCT/JP2022/038340 filed in WO on Oct. 14, 2022

### BACKGROUND

### 1. Technical Field

The present invention relates to a semiconductor device.

### 2. Related Art

Conventionally, in a semiconductor device such as an insulated gate bipolar transistor (IGBT), a structure is known in which a contact trench for connecting an electrode on an upper side of a semiconductor substrate and the semiconductor substrate is provided (see, for example, Patent Documents 1 and 2).

### CITATION LIST

### Patent Document

Patent Document 1: WO 2018/52099

Patent Document 2: Japanese Patent Application Publication No. 2018-195798

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3A illustrates a view showing an example of a cross section e-e in FIG. 2.

FIG. 3B illustrates a view showing another example of the cross section e-e.

FIG. 4A illustrates a perspective cross-sectional view showing an example of a mesa portion 60 of a transistor portion 70.

FIG. 4B illustrates a perspective cross-sectional view showing another example of a mesa portion 60-1 of the transistor portion 70.

FIG. 5 illustrates a perspective cross-sectional view showing an example of a mesa portion 61 of a diode portion 80.

FIG. 6 illustrates a perspective cross-sectional view showing an example of a mesa portion 62 of a boundary portion 72.

FIG. 7A shows an example of a YZ cross section taken along line a-a shown in FIG. 3A.

FIG. 7B shows another example of the YZ cross section taken along line a-a shown in FIG. 3A.

FIG. 8 shows an example of a YZ cross section taken along line b-b shown in FIG. 3A.

FIG. 9 shows an example of a YZ cross section taken along line c-c shown in FIG. 3A.

FIG. 10A shows an XZ cross section in the vicinity of a trench contact portion 55 of the mesa portion 60.

FIG. 10B shows another example of the XZ cross section in the vicinity of the trench contact portion 55 of the mesa portion 60.

FIG. 11 illustrates a view showing another example of the mesa portion 60 of the transistor portion 70.

FIG. 12 illustrates a view showing a YZ cross section of a mesa portion 60-2.

FIG. 13 illustrates a view showing an example of a doping concentration distribution taken along line f-f in FIG. 7.

FIG. 14 illustrates a view showing a structure example of the trench contact portion 55 in each mesa portion.

FIG. 15 illustrates a view showing a structure example of the trench contact portion 55 in each mesa portion.

FIG. 16A illustrates a view showing another example of the mesa portion 60 of the transistor portion 70.

FIG. 16B illustrates a view showing another example of a mesa portion 60-3.

FIG. 17 illustrates a view showing another example of the mesa portion 61 of the diode portion 80.

FIG. 18 illustrates a view showing another example of the mesa portion 61 of the diode portion 80.

FIG. 19 illustrates a view showing an example of a combination of mesa portions in the semiconductor device 100.

FIG. 20 illustrates a view showing another example of the combination of the mesa portions in the semiconductor device 100.

FIG. 21 illustrates a view showing another example of the combination of the mesa portions in the semiconductor device 100.

FIG. 22 illustrates a view showing another example of the combination of the mesa portions in the semiconductor device 100.

FIG. 23 illustrates a view showing another example of the combination of the mesa portions in the semiconductor device 100.

FIG. 24 illustrates a view showing another example of the combination of the mesa portions in the semiconductor device 100.

FIG. 25 illustrates a view showing another example of the combination of the mesa portions in the semiconductor device 100.

FIG. 26 is a cross section e-e showing another configuration example of the semiconductor device 100.

FIG. 27 is a cross section e-e showing another configuration example of the semiconductor device 100.

FIG. 28 illustrates a top view showing another configuration example of the semiconductor device 100.

FIG. 29 illustrates a top view showing another configuration example of the semiconductor device 100.

FIG. 30 illustrates a top view showing another configuration example of the semiconductor device 100.

FIG. 31 illustrates a top view showing another configuration example of the semiconductor device 100.

FIG. 32 illustrates a top view showing another configuration example of the semiconductor device 100.

FIG. 33 illustrates a view showing another configuration example of the semiconductor device 100.

FIG. 34 illustrates a view showing an example of a cross section e-e in FIG. 33.

FIG. 35A illustrates a view showing another configuration example of the semiconductor device 100.

FIG. 35B illustrates a view showing an example of a doping concentration distribution of a cross section a-a and a cross section a′-a′ in FIG. 35A.

FIG. 36 shows an example in which a trench bottom region 260 is added to the structure of the mesa portion 60 shown in FIG. 7A.

FIG. 37 shows an example in which the trench bottom region 260 is added to the structure of the mesa portion 61 shown in FIG. 8.

FIG. 38 shows an example in which the trench bottom region 260 is added to the structure of the mesa portion 62 shown in FIG. 9.

FIG. 39 illustrates a view showing another configuration example of the semiconductor device 100.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis. In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

Further, the region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but the invention is not limited to these. The bulk donor of this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any one of a Czochralski method (CZ method), a magnetic field applied Czochralski method (MCZ method), and a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. Further, as the semiconductor substrate, a non-doped substrate not containing a dopant such as phosphorous may be used. In that case, the bulk donor concentration (DO) of the non-doped substrate is, for example, from 1×10¹⁰/cm ³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5>10¹²/cm³ or less. Each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type. In the present specification, a unit system is an SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or /cm³ is used to indicate a concentration per unit volume. This unit is used for the donor or acceptor concentration, or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

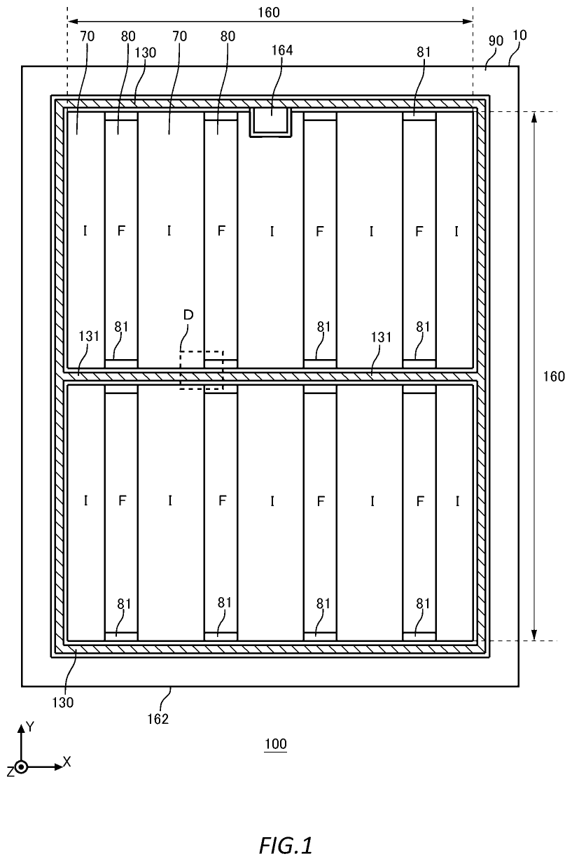

FIG. 1 illustrates a top view showing one example of the semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched by the active portion 160 in the top view may also be included in the active portion 160.

The active portion 160 is provided with a transistor portion 70 including a transistor element such as an IGBT. The active portion 160 may further be provided with a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. A collector region of P+ type of may be provided in a region other than the cathode region on the lower surface of the semiconductor substrate 10. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. Further, a well region is formed below the gate runner. The well region is a region of the P type having a higher concentration than the base region described below, and is formed up to a position deeper than the base region from the upper surface of the semiconductor substrate 10. A region surrounded by the well region in the top view may be the active portion 160. Further, the outer circumferential gate runner 130 is connected to the gate pad 164. The outer circumferential gate runner 130 is arranged above the semiconductor substrate 10. The outer circumferential gate runner 130 may be a metal wiring including aluminum.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 substantially at the center of the Y axis direction, the outer circumferential gate runner 130 enclosing the active portion 160. When the active portion 160 is divided by the active-side gate runner 131, the transistor portion 70 and the diode portion 80 may be alternately arranged in the X axis direction in each divided region.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

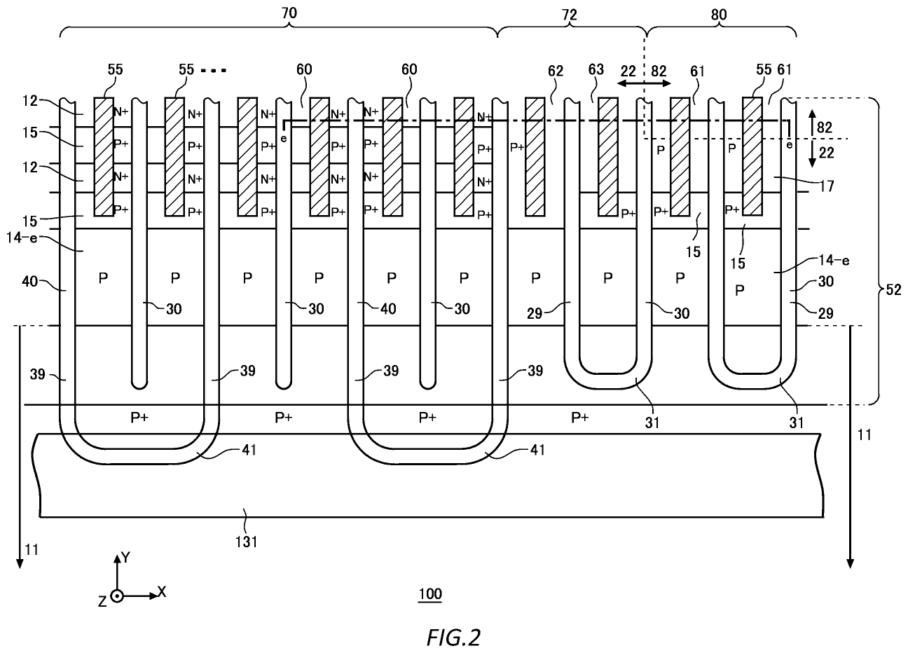

FIG. 2 illustrates an enlarged view of a region D in FIG. 1. The region D is a region including the transistor portion 70, the diode portion 80, and the active-side gate runner 131. As illustrated in FIG. 2, a boundary portion 72 may be provided between the transistor portion 70 and the diode portion 80. The semiconductor device 100 of this example includes one or more gate trench portions 40, one or more dummy trench portions 30, a well region 11, one or more emitter regions 12, one or more base regions 14, and one or more contact regions 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole is provided passing through the interlayer dielectric film. A conductive member such as the emitter electrode 52 may be provided inside the contact hole.

A trench contact portion 55 is provided on the upper surface of the semiconductor substrate 10 of this example. The trench contact portion 55 is a member in which a groove-shaped structure provided from the upper surface of the semiconductor substrate 10 to a predetermined depth is filled with a conductive material. The inside of the groove of the trench contact portion 55 is filled with a conductive member such as tungsten. Inside the groove of the trench contact portion 55, a barrier metal including at least one of a titanium film and a titanium nitride film may be provided between the conductive member and the semiconductor substrate 10. One or more trench contact portions 55 are provided to extend in the extending direction (Y axis direction). The trench contact portion 55 is arranged below the contact hole of the interlayer dielectric film described above. The emitter electrode 52 may be connected to the semiconductor substrate 10 via the contact hole of the interlayer dielectric film and the trench contact portion 55. In FIG. 2, each trench contact portion 55 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with at least part of the well region 11, the emitter region 12, the contact region 15, an anode region 17, and the base region 14 on the upper surface of the semiconductor substrate 10, via the contact hole and the trench contact portion 55. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole in the Y axis direction toward the active-side gate runner 131 side. The well region 11 is a region of a second conductivity type in which the doping concentration is higher than the base region 14. The base region 14 of this example is a P type, and the well region 11 is a P+ type.

Each of the transistor portion 70, the boundary portion 72, and the diode portion 80 includes one or more trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 is provided along the array direction. In the diode portion 80 of this example, the gate trench portion 40 is not provided. In the boundary portion 72 of this example, one or more dummy trench portions 30 are provided along the array direction. In the boundary portion 72, the gate trench portion 40 may be further provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, the transistor portion 70 is provided with a mesa portion 60, the diode portion 80 is provided with a mesa portion 61, and the boundary portion 72 is provided with a mesa portion 62 and a mesa portion 63. The mesa portion 62 is a mesa portion closest to the transistor portion 70 at the boundary portion 72, and the mesa portion 63 is a mesa portion closest to the diode portion 80 at the boundary portion 72. One or more mesa portions 62 may be further provided between the mesa portion 62 and the mesa portion 63. One or more mesa portions 63 may be further provided between the mesa portion 62 and the mesa portion 63. When merely referred to as the mesa portion in the present specification, it means each of the mesa portion 60, the mesa portion 61, the mesa portion 62, and the mesa portion 63.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at the other end portion of each mesa portion. Each mesa portion may be provided with at least any one of the emitter region 12 of a first conductivity type, the contact region 15 of the second conductivity type, and the anode region 17 of the second conductivity type in a region sandwiched between the base regions 14-e in the top view. The emitter region 12 of this example is an N+type, the contact region 15 is a P+type, and the anode region 17 is a P type. The emitter region 12 and the contact region 15 may be provided between the base region 14 and the upper surface of the semiconductor substrate 10 in the depth direction. The anode region 17 may be provided in the same depth range as that of the base region 14. The anode region 17 may have the same doping concentration as that of the one or more base regions 14, and may have a lower doping concentration than that of the one or more base regions 14.

The mesa portion 60 of the transistor portion 70 has the emitter region 12 exposed on the upper surface of the semiconductor substrate 10. The one or more emitter regions 12 are provided in contact with the one or more gate trench portions 40. The mesa portion 60 in contact with the gate trench portion 40 may be provided with the one or more contact regions 15 exposed on the upper surface of the semiconductor substrate 10.

Each of the contact region 15 and the emitter region 12 in the mesa portion 60 is provided from one trench portion to the other trench portion in the X axis direction. As an example, the one or more contact regions 15 and the one or more emitter regions 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14, the anode region 17, and the contact region 15 may be provided on an upper surface of the mesa portion 61. In the region sandwiched between the base regions 14-e on the upper surface of the mesa portion 61, the contact region 15 may be provided in contact with each base region 14-e. The anode region 17 may be provided in a region sandwiched between the contact regions 15 on the upper surface of the mesa portion 61. The anode region 17 may be arranged in the entire region sandwiched between the contact regions 15.

The contact region 15 may be provided on the upper surface of the mesa portion 62 of the boundary portion 72. In this example, the entire region sandwiched between the base regions 14-e on the upper surface of the mesa portion 61 is the contact region 15.

The mesa portion 63 of the boundary portion 72 is not provided with the emitter region 12. The base region 14, the anode region 17, and the contact region 15 may be provided on the upper surface of the mesa portion 63. In the region sandwiched between the base regions 14-e on the upper surface of the mesa portion 63, the contact region 15 may be provided in contact with each of the base regions 14-e. The anode region 17 may be provided in the region sandwiched between the contact regions 15 on the upper surface of the mesa portion 63. The anode region 17 may be arranged in the entire region sandwiched between the contact regions 15. In the example of FIG. 2, the structures of the mesa portion 61 and the mesa portion 63 are the same. In another example, the mesa portion 63 may have a structure different from that of the mesa portion 61.

The trench contact portion 55 is provided in each mesa portion. A contact hole is provided in the interlayer dielectric film above the trench contact portion 55. The trench contact portion 55 is arranged in the region sandwiched between the base regions 14-e. The trench contact portion 55 of this example is provided above each region of the contact region 15, the base region 14, the anode region 17, and the emitter region 12. The trench contact portion 55 is not provided in the regions corresponding to the base region 14-e and the well region 11. The trench contact portion 55 may be arranged at the center of each mesa portion in the array direction (X axis direction).

In the diode portion 80, a cathode region 82 of the N+ type is provided in a region in contact with the lower surface of the semiconductor substrate 10. On the lower surface of the semiconductor substrate 10, a collector region of the P+ type 22 may be provided in a region where the cathode region 82 is not provided. In the transistor portion 70 and the boundary portion 72, the collector region 22 is provided in a region in contact with the lower surface of the semiconductor substrate 10. In FIG. 2, a boundary between the cathode region 82 and the collector region 22 is indicated by a dotted line.

The cathode region 82 is arranged separately from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 of this example is arranged farther away from the well region 11 than the end portion in the Y axis direction of the trench contact portion 55. In another example, the end portion in the Y axis direction of the cathode region 82 may be arranged between the well region 11 and the trench contact portion 55.

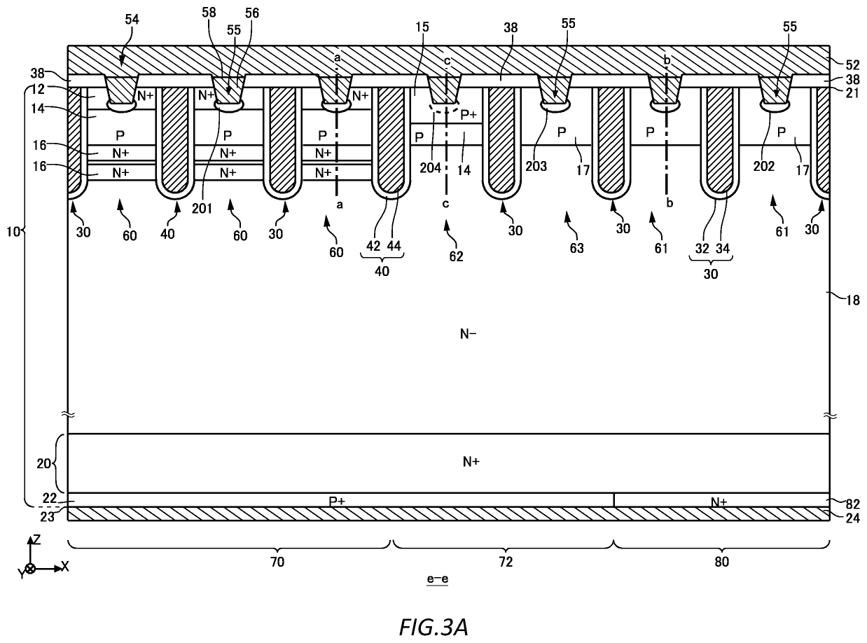

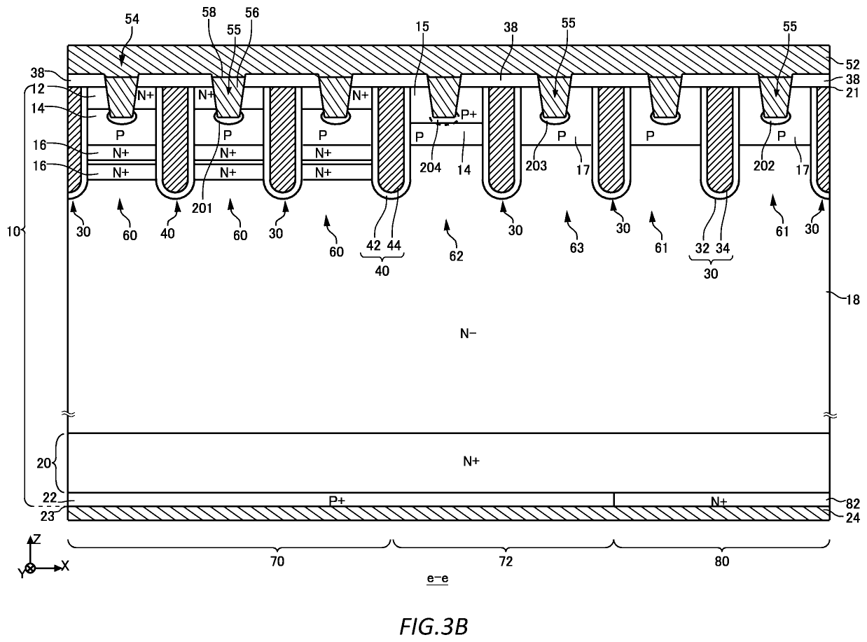

FIG. 3A illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with the contact hole 54 described in FIG. 2.

The emitter electrode 52 is provided on the upper side of the interlayer dielectric film 38. The emitter electrode 52 is connected to the semiconductor substrate 10 through the contact hole 54 of the interlayer dielectric film 38. The inside of the contact hole 54 may be filled with the same conductive material as that of the emitter electrode 52 above the interlayer dielectric film 38, or may be filled with a different conductive material. The collector electrode 24 is provided on a lower surface 23 of the semiconductor substrate 10. The emitter electrode 52 and the collector electrode 24 are formed of a metal material such as aluminum. The inside of the contact hole 54 may be filled with tungsten or the like. In the specification, the direction in which the emitter electrode 52 is connected to the collector electrode 24 (the Z axis direction) is referred to as a depth direction.

The semiconductor substrate 10 includes an N type or N- type of drift region 18. The drift region 18 is provided in each of the transistor portion 70, the boundary portion 72, and the diode portion 80.

In the mesa portion 60 of the transistor portion 70, an N+ type of emitter region 12 and a P type of base region 14 are provided in order from an upper surface 21 side of the semiconductor substrate 10. The drift region 18 is provided below the base region 14. The mesa portion 60 may be provided with an N+ type of accumulation region 16. The accumulation region 16 is arranged between the one or more base regions 14 and the drift region 18.

The one or more emitter regions 12 are exposed on the upper surface 21 of the semiconductor substrate 10 and are provided in contact with gate trench portion 40. The one or more emitter regions 12 may be in contact with the trench portions on both sides of the mesa portion 60. The emitter region 12 has a higher doping concentration than the drift region 18.

The one or more base regions 14 are provided below the emitter region 12. The base region 14 of this example is provided in contact with the emitter region 12. The one or more base regions 14 may be in contact with the one or more trench portions on both sides of the mesa portion 60.

The accumulation region 16 is provided below the base region 14. The accumulation region 16 is an N+ type region with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 60 may be provided with two or more accumulation regions 16 in the depth direction. Each accumulation region 16 has a peak of the doping concentration in the depth direction. A valley of the doping concentration in the depth direction is provided between two accumulation regions 16. That is, the mesa portion 60 may have two or more doping concentration peaks from the base region 14 toward the drift region 18. The drift region 18 may be provided between the accumulation region 16 and the base region 14, and the accumulation region 16 and the base region 14 may be in contact with each other. The accumulation region 16 may be provided or may not be provided in the boundary portion 72 and the diode portion 80. In this example, neither the boundary portion 72 nor the diode portion 80 is provided with the accumulation region 16.

The mesa portion 61 of the diode portion 80 is provided with the anode region 17 of the P type in contact with the upper surface 21 of the semiconductor substrate 10. The drift region 18 is provided below the anode region 17. Note that in the structure of any mesa portion 61 described in the present specification, the anode region 17 may have the same doping concentration as that of the base region 14, and may have a doping concentration lower than that of the base region 14. By reducing the concentration of the anode region 17, hole implantation in the mesa portion 61 can be suppressed, and a reverse recovery loss can be reduced.

The mesa portion 62 of the boundary portion 72 is provided with the contact region 15 of the P+ type in contact with the upper surface 21 of the semiconductor substrate 10. The base region 14 or the anode region 17 may be provided between the contact region 15 and the drift region 18, and the contact region 15 and the drift region 18 may be in contact with each other.

The mesa portion 63 of the boundary portion 72 is provided with the anode region 17 of the P type in contact with the upper surface 21 of the semiconductor substrate 10. The drift region 18 is provided below the anode region 17.

In each of the transistor portion 70, the boundary portion 72, and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 in this example may have two or more concentration peaks in the depth direction (Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region of the P+ type 22 and the cathode region 82 of the N+ type.

In the transistor portion 70 and the boundary portion 72, the collector region of the P+ type 22 is provided below the buffer region 20. A doping concentration of the collector region 22 is higher than a doping concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A doping concentration of the cathode region 82 is higher than a doping concentration of the drift region 18. A donor of the cathode region 82 is, for example, hydrogen or phosphorous. Note that an element serving as a donor and an acceptor in each region is not limited to the above described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum. Note that in the diode portion 80, a part of the cathode region 82 may be replaced with a region of the P type. The P type region is arranged to be sandwiched between the cathode regions 82. The P type region may be sandwiched between the cathode regions 82 in the Y axis direction.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided up to below the base region 14. In a region where at least any one of the emitter region 12, the contact region 15, and the accumulation region 16 is provided, each trench portion also passes through the doping regions of these. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and the dummy trench portion 30. In the boundary portion 72, the dummy trench portion 30 is provided. In the boundary portion 72, the gate trench portion 40 may be further provided. In the diode portion 80, the dummy trench portion 30 is provided, and the gate trench portion 40 is not provided.

A boundary between the collector region 22 and the cathode region 82 may be set as a boundary between the boundary portion 72 and the diode portion 80 in the X axis direction. When the boundary portion 72 is not provided, a boundary between the collector region 22 and the cathode region 82 may be set as a boundary between the transistor portion 70 and the diode portion 80 in the X axis direction. Further, among the trench portions in contact with the emitter region 12, the trench portion closest to the diode portion 80 may be set as a boundary between the transistor portion 70 and the boundary portion 72.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross section) convexly downward.

At least one mesa portion 60 of the transistor portion 70 is provided with the trench contact portion 55 and a first bottom region 201 of the second conductivity type. All the mesa portions 60 may be provided with the trench contact portion 55 and the first bottom region 201. In the cross section illustrated in FIG. 3A, the trench contact portion 55 is provided in the depth direction from the upper surface 21 toward the lower surface 23 of the semiconductor substrate 10. The one or more trench contact portions 55 of this example are formed more shallowly than the lower end of the emitter region 12. The trench contact portion 55 of another example may be provided to the same depth as the lower end of the emitter region 12, or may be formed more deeply than the lower end of the emitter region 12.

A plug 56 made of metal such as tungsten may be embedded in the trench contact portion 55. When the plug 56 is embedded in the trench contact portion 55, the upper surface 58 of the plug 56 may be set as the upper surface 58 of the trench contact portion 55. The upper surface 58 of the plug 56 may be positioned on the emitter electrode 52 side (that is, above) relative to the upper surface 21 of the semiconductor substrate 10. When the upper surface 58 of the plug 56 is positioned on the emitter electrode 52 side relative to the upper surface 21, the trench contact portion 55 may be provided from the upper surface 58 of the plug 56 to the lower surface 23 side relative to the upper surface 21 of the semiconductor substrate 10. That is, the upper surface 58 of the trench contact portion 55 may be positioned on the upper surface 21 side relative to the upper surface of the interlayer dielectric film 38, or may be positioned on the emitter electrode 52 side relative to the upper surface 21. Alternatively, the upper surface 58 of the trench contact portion 55 may be provided up to the same depth position as the upper surface of the interlayer dielectric film 38.

The first bottom region 201 in this example is a P+ type region with a higher doping concentration than the base region 14. The first bottom region 201 is provided in contact with the bottom of any one of the one or more trench contact portions 55. The first bottom region 201 is connected to the base region 14. At least a part of a region of the first bottom region 201 is provided below the emitter region 12. The first bottom region 201 is provided to extend in the Y axis direction along the trench contact portion 55. The first bottom region 201 is connected to the contact region 15 illustrated in FIG. 2. According to this example, when the transistor portion 70 is turned off, holes directed from the lower surface 23 side toward the emitter region 12 can flow to the contact region 15 or the trench contact portion 55 via the first bottom region 201. With this configuration, a resistance of a path through which the holes pass can be lowered, and latch-up can be suppressed.

At least one mesa portion 61 of the diode portion 80 is provided with the trench contact portion 55 and a second bottom region 202 of the second conductivity type. All the mesa portions 61 may be provided with the trench contact portion 55 and the second bottom region 202. The trench contact portion 55 of the diode portion 80 may have the same structure as the trench contact portion 55 of the transistor portion 70. The lower end of the trench contact portion 55 of the diode portion 80 may be arranged inside the anode region 17.

The second bottom region 202 in this example is a P+ type region with a higher doping concentration than the anode region 17 and the base region 14. The second bottom region 202 is provided in contact with the bottom of any one of the one or more trench contact portions 55. The second bottom region 202 may be provided inside the anode region 17. That is, the second bottom region 202 may not be in contact with the drift region 18. The second bottom region 202 is provided to extend in the Y axis direction along the trench contact portion 55. A contact resistance between the emitter electrode 52 and the semiconductor substrate 10 can be reduced by providing the second bottom region 202.

The length of the first bottom region 201 in the Y axis direction is larger than the length of the second bottom region 202 in the Y axis direction. The implantation amount of holes from the upper surface 21 side in the mesa portion 61 can be reduced by reducing the size of the second bottom region 202. Therefore, the reverse recovery time of the diode portion 80 can be shortened, and the reverse recovery loss can be reduced.

The trench contact portion 55 is provided in the mesa portion 62 of the boundary portion 72. The mesa portion 62 of the boundary portion 72 may be provided closest to the transistor portion 70 side in the boundary portion 72. The trench contact portion 55 of the mesa portion 62 may have the same structure as the trench contact portion 55 of the transistor portion 70. The lower end of the trench contact portion 55 of the mesa portion 62 is arranged inside the contact region 15. A P type bottom region with a higher doping concentration than the contact region 15 is not provided at the lower end of the trench contact portion 55 of the mesa portion 62. In another example, a P type bottom region 204 with a higher doping concentration than the contact region 15 may be provided at the lower end of the trench contact portion 55 of the mesa portion 62. In FIG. 3A, a position when the bottom region 204 is provided is indicated by a dotted line. As the doping concentration of the contact region 15, the doping concentration of the mesa portion 62 on the upper surface 21 may be used.

The mesa portion 63 of the boundary portion 72 is provided with the trench contact portion 55 and a third bottom region 203 of the second conductivity type. The mesa portion 63 of the boundary portion 72 may be provided on the diode portion 80 side relative to the mesa portion 62 of the boundary portion 72. All the mesa portions 63 may be provided with the trench contact portion 55 and the third bottom region 203. The trench contact portion 55 of the mesa portion 63 may have the same structure as the trench contact portion 55 of the transistor portion 70. The lower end of the trench contact portion 55 of the mesa portion 63 may be arranged inside the anode region 17.

The third bottom region 203 in this example is a P+ type region with a higher doping concentration than the anode region 17 and the base region 14. The third bottom region 203 is provided in contact with the bottom of any one of the one or more trench contact portions 55. The third bottom region 203 may be provided inside the anode region 17. That is, the third bottom region 203 may not be in contact with the drift region 18. The third bottom region 203 is provided to extend in the Y axis direction along the trench contact portion 55. The contact resistance between the emitter electrode 52 and the semiconductor substrate 10 can be reduced by providing the third bottom region 203.

The length of the first bottom region 201 in the Y axis direction is larger than the length of the third bottom region 203 in the Y axis direction. The implantation amount of holes from the upper surface 21 side in the mesa portion 63 arranged in the vicinity of the diode portion 80 can be reduced by reducing the size of the third bottom region 203. Therefore, the reverse recovery time of the diode portion 80 can be shortened, and the reverse recovery loss can be reduced. The doping concentration, the size, the shape, and the position on the Y axis of the third bottom region 203 may be the same as those of the second bottom region 202.

In FIG. 3A or the like, the boundary portion 72 has one mesa portion 62 and one mesa portion 63. In another example, the boundary portion 72 may have a plurality of mesa portions 63 between the mesa portion 62 and the diode portion 80. Further, the boundary portion 72 may have a plurality of mesa portions 62 between the mesa portion 63 and the transistor portion 70. By providing the boundary portion 72, a distance between the transistor portion 70 and the diode portion 80 is ensured, and for example, a current can be suppressed from flowing between the mesa portion 60 and the cathode region 82.

FIG. 3B illustrates a view showing another example of the cross section e-e. In this example, the trench contact portion 55 is formed more deeply than the example of FIG. 3A. Other structures may be similar to those of the semiconductor device 100 illustrated in FIG. 3A.

In the mesa portion 60, the trench contact portion 55 is formed more deeply than the emitter region 12. That is, the trench contact portion 55 penetrates the emitter region 12, and the lower end of the trench contact portion 55 is arranged below the lower end of the emitter region 12. The lower end of the trench contact portion 55 of the mesa portion 60 may be arranged at the same depth as the base region 14.

The trench contact portion 55 of another mesa portion may also have the same structure as the mesa portion 60. In this case, the lower end of the trench contact portion 55 of the mesa portion 61 may be arranged at the same depth as the anode region 17. The lower end of the trench contact portion 55 of the mesa portion 62 may be arranged at the same depth as the contact region 15, or may be arranged at the same depth as the base region 14 below the contact region 15. The lower end of the trench contact portion 55 of the mesa portion 63 may be arranged at the same depth as the anode region 17.

Further, the trench contact portion 55 of another mesa portion may have the structure illustrated in FIG. 3A. That is, the trench contact portion 55 of another mesa portion may be formed more shallowly than the trench contact portion 55 of the mesa portion 60.

Similarly to the example of FIG. 3A, the bottom region (201, 202, 203, or 204) may be formed at the bottom of each trench contact portion 55. The bottom region 201 may be separate from the emitter region 12 or may be in contact with the emitter region 12. The lower end of the bottom region 201 may be arranged at the same depth as the base region 14. The lower ends of the bottom region 202 and the bottom region 203 may be arranged at the same depth as the anode region 17. The lower end of the bottom region 204 may be arranged at the same depth as the contact region 15, or may be arranged at the same depth as the base region 14.

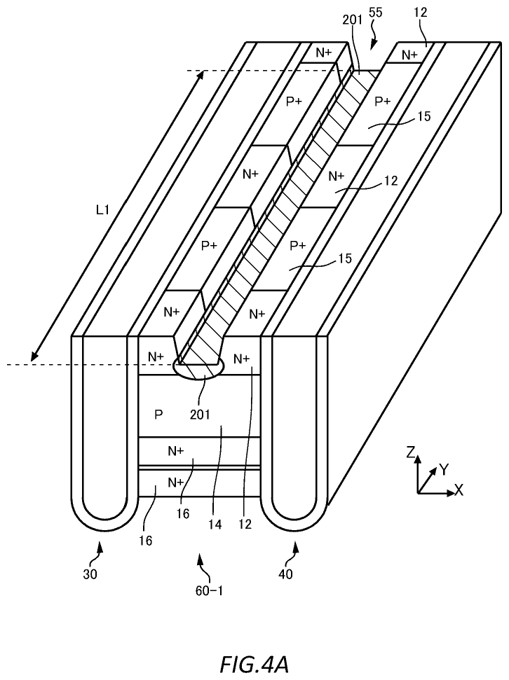

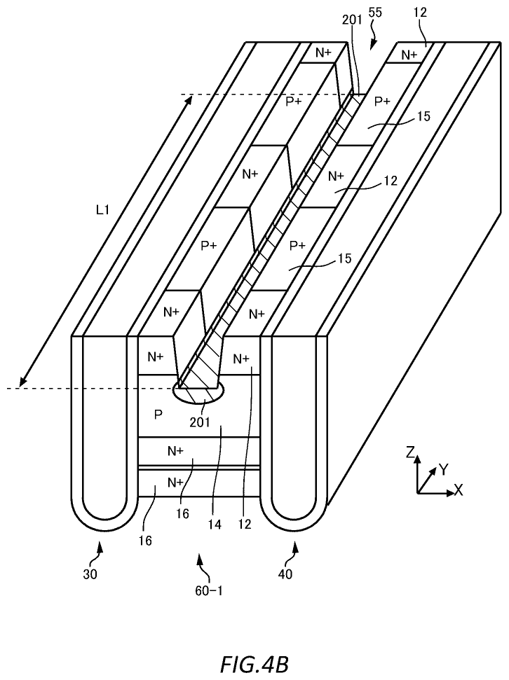

FIG. 4A illustrates a perspective cross-sectional view showing an example of the mesa portion 60 of the transistor portion 70. The mesa portion 60 illustrated in FIG. 4A may be referred to as a mesa portion 60-1. FIG. 4A illustrates an XZ cross section and an upper surface (XY plane) of the mesa portion 60-1 and a side surface (YZ plane) of the trench portion.

The structure of the mesa portion 60-1 in the XZ cross section is similar to that of the mesa portion 60 illustrated in FIG. 3A. The structure of the mesa portion 60-1 on the upper surface is similar to that of the mesa portion 60 illustrated in FIG. 2. On the upper surface of the mesa portion 60-1, the emitter regions 12 and the contact regions 15 are alternately arranged along the Y axis direction. Further, the trench contact portion 55 is provided at the center of the mesa portion 60-1 in the X axis direction. Note that in FIG. 4A, the metal inside the trench contact portion 55 is omitted, and the groove structure of the trench contact portion 55 is illustrated.

As described above, the first bottom region 201 is provided to extend in the Y axis direction along the bottom surface of the trench contact portion 55. In FIG. 4A, the first bottom region 201 is hatched with diagonal lines. A length L1 of the first bottom region 201 in the Y axis direction may be the same as the length of the trench contact portion 55 in the Y axis direction. The length L1 of the first bottom region 201 is the length of the first bottom region 201 provided continuously along the Y axis direction.

The first bottom region 201 may be formed by forming the groove structure of the trench contact portion 55, then implanting acceptor ions from the groove structure, and heat-treating the semiconductor substrate 10. Since the acceptor ions are diffused by the heat treatment, the length L1 of the first bottom region 201 may be slightly larger than the length of the trench contact portion 55 in the Y axis direction. A difference between the length L1 and the length of the trench contact portion 55 may be 10 μm or less, or may be 5 μm or less. Note that the length L1 may be smaller than the length of the one or more trench contact portions 55. By masking a part of the groove structure of the contact hole 54 or a part of the groove structure of the trench contact portion 55 and implanting acceptor ions, the first bottom region 201 shorter than the trench contact portion 55 can be formed.

The length L1 of the first bottom region 201 may be smaller than the length of the trench portion (the gate trench portion 40 or the dummy trench portion 30), which is arranged closest thereto, in the Y axis direction. The first bottom region 201 may be separate from the well region 11 illustrated in FIG. 2.

The width of the first bottom region 201 in the X axis direction may be the same as the width of the bottom surface of the trench contact portion 55, or may be larger than the width of the bottom surface of the trench contact portion 55. The bottom surface of the trench contact portion 55 may be a surface of the trench contact portion 55 formed closest to the lower surface 23 side. The width of the first bottom region 201 in the X axis direction in this example is larger than the width of the bottom surface of the trench contact portion 55. The width of the first bottom region 201 in the X axis direction is smaller than the width of the mesa portion 60 in the X axis direction. The first bottom region 201 is provided away from the trench portion.

The first bottom region 201 may be exposed to the entire bottom surface of the trench contact portion 55. The first bottom region 201 may also be exposed on a part of the side surface of the groove structure of the trench contact portion 55.

FIG. 4B illustrates a perspective cross-sectional view showing another example of the mesa portion 60-1 of the transistor portion 70. The structure of the mesa portion 60-1 in the XZ cross section of this example is similar to that of the mesa portion 60 illustrated in FIG. 3B. The structure of the mesa portion 60-1 on the upper surface is similar to that of the mesa portion 60 illustrated in FIG. 2. That is, the mesa portion 60-1 of this example is different from the mesa portion 60-1 illustrated in FIG. 4A in that the trench contact portion 55 penetrates the emitter region 12. As the trench contact portion 55 is formed deeply, the bottom region 201 is also provided at a position deeper than that in the example of FIG. 4A. Other structures are similar to those in the example of FIG. 4A.

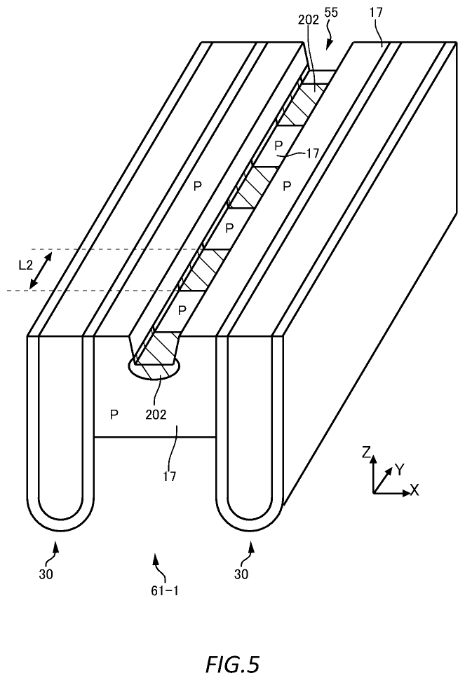

FIG. 5 illustrates a perspective cross-sectional view showing an example of the mesa portion 61 of the diode portion 80. The mesa portion 61 illustrated in FIG. 5 may be referred to as a mesa portion 61-1. FIG. 5 illustrates an XZ cross section and an upper surface (XY plane) of the mesa portion 61-1 and a side surface (YZ plane) of the trench portion.

The structure of the mesa portion 61-1 in the XZ cross section is similar to that of the mesa portion 61 illustrated in FIG. 3A. The structure of the mesa portion 61-1 on the upper surface is similar to that of the mesa portion 61 illustrated in FIG. 2. The anode region 17 and the trench contact portion 55 are arranged on the upper surface of the mesa portion 61-1. The structure of the trench contact portion 55 is similar to that of the trench contact portion 55 of FIG. 4A.

As described above, the second bottom region 202 is exposed on the bottom surface of the trench contact portion 55. The second bottom region 202 may also be exposed on a part of the side surface of the groove structure of the trench contact portion 55. In FIG. 5, the second bottom region 202 is hatched with diagonal lines. A length L2 of the second bottom region 202 in the Y axis direction is smaller than the length of the trench contact portion 55 in the Y axis direction. In the mesa portion 61-1 of this example, a plurality of second bottom regions 202 is discretely arranged along the Y axis direction. The plurality of second bottom regions 202 may be arranged at regular intervals in the Y axis direction. The length L2 of the second bottom region 202 is the length of one second bottom region 202 provided continuously along the Y axis direction. Similarly to the trench contact portion 55 illustrated in FIG. 4B, the trench contact portion 55 of the mesa portion 61-1 may be formed more deeply.

The length L1 of the first bottom region 201 illustrated in FIG. 4A or 4B is larger than the length L2 of the second bottom region 202. With this configuration, it is possible to suppress implantation of holes in the diode portion 80 while suppressing latch-up in the transistor portion 70. Further, by providing the second bottom region 202 in the diode portion 80, a contact property between the emitter electrode 52 and the anode region 17 in the diode portion 80 can be improved.

The length L1 may be 2 times or more, 5 times or more, or 10 times or more the length L2. The sum (referred to as a first sum) of the lengths L1 of one or more first bottom regions 201 in one mesa portion 60 is larger than the sum (referred to as a second sum) of the lengths L2 of the plurality of second bottom regions 202 in one mesa portion 61. The first sum may be 1.5 times or more, 2 times or more, or 3 times or more the second sum. The total area (first total area) of one or more first bottom regions 201 in one mesa portion 60 in the top view is larger than the total area (referred to as a second total area) of the plurality of second bottom regions 202 in one mesa portion 61 in the top view. The first total area may be 1.5 times or more, 2 times or more, or 3 times or more the second total area.

The second bottom region 202 may be formed in a manner similar to that of the first bottom region 201. However, when the second bottom region 202 is formed, acceptor ions are selectively implanted into the trench contact portion 55. The second bottom region 202 may be separate from the well region 11 illustrated in FIG. 2.

The width of the second bottom region 202 in the X axis direction may be the same as the width of the trench contact portion 55, or may be larger than the width of the trench contact portion 55. The width of the second bottom region 202 in the X axis direction is smaller than the width of the mesa portion 61 in the X axis direction. The second bottom region 202 is provided away from the trench portion.

The width of the second bottom region 202 in the X axis direction may be the same as or different from the width of the first bottom region 201 in the X axis direction. The width of the second bottom region 202 in the X axis direction may be smaller than the width of the first bottom region 201 in the X axis direction. In this case, hole implantation in the diode portion 80 can be further suppressed.

The doping concentration of the second bottom region 202 may be the same as or different from the doping concentration of the first bottom region 201. The doping concentration of the second bottom region 202 may be lower than the doping concentration of the first bottom region 201. In this case, hole implantation in the diode portion 80 can be further suppressed.

The mesa portion 63 of the boundary portion 72 may have the same structure as the mesa portion 61 of the diode portion 80. For example, the mesa portion 63 has a third bottom region 203 instead of the second bottom region 202 in the mesa portion 61. Other structures are similar to those in the mesa portion 61.

The shape, size, and arrangement of the third bottom region 203 may be the same as those of the second bottom region 202. That is, the length L1 of the first bottom region 201 in the Y axis direction is larger than the length of the third bottom region 203 in the Y axis extending direction. Further, the length L2 of the second bottom region 202 in the Y axis direction may be the same as the length of the third bottom region 203 in the Y axis direction. In another example, the second bottom region 202 may be longer or shorter than the third bottom region 203. The doping concentration of the third bottom region 203 may be the same as or different from the doping concentration of the second bottom region 202.

Further, at least one mesa portion 63 may not be provided with the third bottom region 203. For example, the mesa portion 63 closest to the diode portion 80 may not be provided with the third bottom region 203. Since the cathode region 82 is not provided below the mesa portion 63 and the mesa portion does not function as the diode portion 80, a contact property between the mesa portion 63 and the emitter electrode 52 may be low. Further, the hole implantation amount in the vicinity of the diode portion 80 can be suppressed by omitting the third bottom region 203.

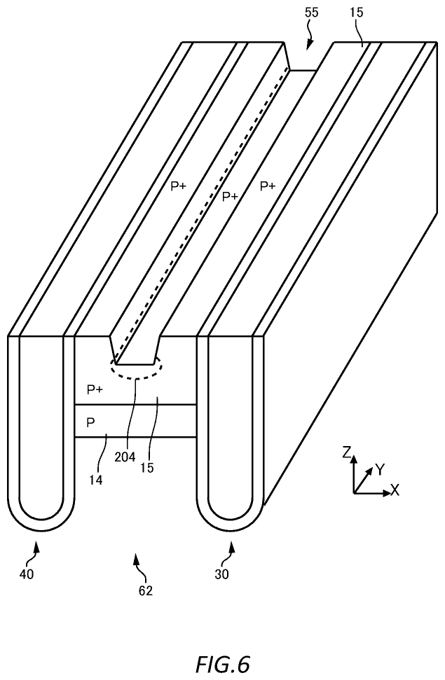

FIG. 6 illustrates a perspective cross-sectional view showing an example of the mesa portion 62 of the boundary portion 72. FIG. 6 illustrates an XZ cross section and an upper surface (XY plane) of the mesa portion 62 and a side surface (YZ plane) of the trench portion. The structure of the mesa portion 62 in the XZ cross section is similar to that of the mesa portion 62 illustrated in FIG. 3A. The structure of the mesa portion 62 on the upper surface is similar to that of the mesa portion 62 illustrated in FIG. 2. The contact region 15 and the trench contact portion 55 are arranged on the upper surface of the mesa portion 62. The structure of the trench contact portion 55 is similar to that of the trench contact portion 55 of FIG. 4A. The contact region 15 is exposed on the bottom surface and the side surface of the trench contact portion 55 of the mesa portion 62. When the bottom region 204 is provided on the bottom surface of the trench contact portion 55 of the mesa portion 62, the bottom region 204 is exposed on the bottom surface and the side surface of the trench contact portion 55 of the mesa portion 62. Similarly to the trench contact portion 55 illustrated in FIG. 4B, the trench contact portion 55 of the mesa portion 62 may be formed more deeply.

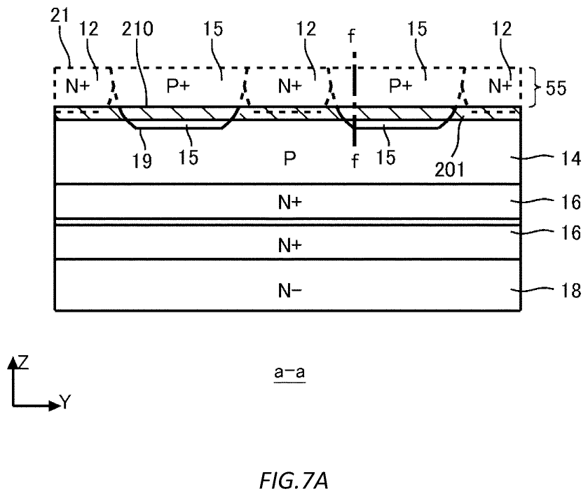

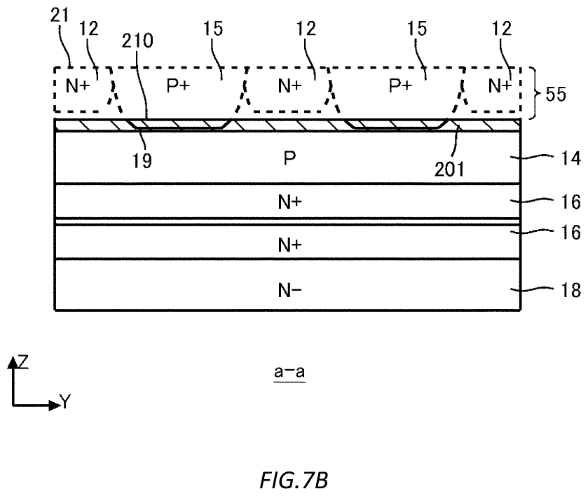

FIG. 7A shows an example of a YZ cross section taken along line a-a shown in FIG. 3A. FIG. 7A shows a cross section of the mesa portion 60 of the transistor portion 70. The cross section passes through the trench contact portion 55. In FIG. 7A, the emitter region 12 and the contact region 15 projected on the cross section are indicated by a broken line.

The contact regions 15 and the emitter regions 12 are alternately arranged in the Y axis direction. The contact region 15 and the emitter region 12 are formed up to a predetermined depth from the upper surface 21 of the semiconductor substrate 10. The contact region 15 may be formed up to below the emitter region 12.

The first bottom region 201 connects two of the one or more contact regions 15 arranged away from each other in the Y axis direction. The first bottom region 201 may connect all the contact regions 15 provided in the mesa portion 60.

As an example of a manufacturing method of the semiconductor device 100, the groove structure of the trench contact portion 55 may be formed after the emitter region 12 and the contact region 15 are formed on the upper surface 21 of the semiconductor substrate 10. When the groove structure is formed, a part of the emitter region 12 and the contact region 15 are removed. The groove structure is preferably formed more shallowly than the lower end of the contact region 15. That is, the contact region 15 remains below the groove structure. The groove structure may be formed more shallowly than the lower end of the emitter region 12, and may be formed more deeply than the lower end of the emitter region 12. In the example of FIG. 7A, the groove structure of the trench contact portion 55 is more shallowly than the lower end of the emitter region 12. That is, the emitter region 12 remains below the bottom surface 210 of the groove structure.

Next, acceptor ions are implanted from the bottom surface 210 of the groove structure to form the first bottom region 201. At this time, the acceptor ions are implanted at a dose amount that allows the emitter region 12 below the bottom surface 210 to be inverted to a region of the P type. The bottom of the emitter region 12 indicated by the broken line in FIG. 7A corresponds to the bottom of the emitter region 12 before implanting acceptor ions. Acceptor ions may also be implanted into a region where the contact region 15 is formed. That is, the first bottom region 201 may be formed to overlap the contact region 15. A portion where the first bottom region 201 and the contact region 15 overlap each other has a higher doping concentration than the original doping concentration of the contact region 15 since the doping concentrations of the respective regions overlap each other. In the present specification, a portion where the contact region 15 and the first bottom region 201 overlap each other is also referred to as the first bottom region 201. In the first bottom region 201, portions with relatively high doping concentrations and portions with relatively low doping concentrations may be alternately arranged along the Y axis direction. In the first bottom region 201 of this example, the doping concentration of the portion overlapping the contact region 15 is higher than the doping concentration of the portion overlapping the emitter region 12.

The first bottom region 201 may have a portion formed at a position deeper than the emitter region 12. At least a part of the first bottom region 201 is provided on the upper surface 21 side relative to the lower end 19 of each of the one or more contact regions 15. In the example of FIG. 7A, the entire first bottom region 201 is arranged above the lower end 19 of the contact region 15. By protruding the contact region 15 downward, the holes attracted to the emitter region 12 can be easily extracted via the contact region 15.

According to this example, hole carriers directed from the drift region 18 toward the emitter region 12 can flow to the contact region 15 or the trench contact portion 55 via the first bottom region 201. Therefore, latch-up of the transistor portion 70 can be suppressed.

FIG. 7B shows another example of the YZ cross section taken along line a-a shown in FIG. 3A. The mesa portion 60-1 of this example is different from the mesa portion 60-1 illustrated in FIG. 7A in that the trench contact portion 55 penetrates the emitter region 12. That is, the bottom surface 210 of the trench contact portion 55 is formed more deeply than the lower end of the emitter region 12. As the trench contact portion 55 is formed deeply, the bottom region 201 is also provided at a position deeper than that in the example of FIG. 7A. Other structures are similar to those in the example of FIG. 7A. The bottom region 201 of this example also connects two contact regions 15 adjacent to each other in the Y axis direction. The bottom region 201 may be separate from or in contact with the emitter region 12 in the Z axis direction.

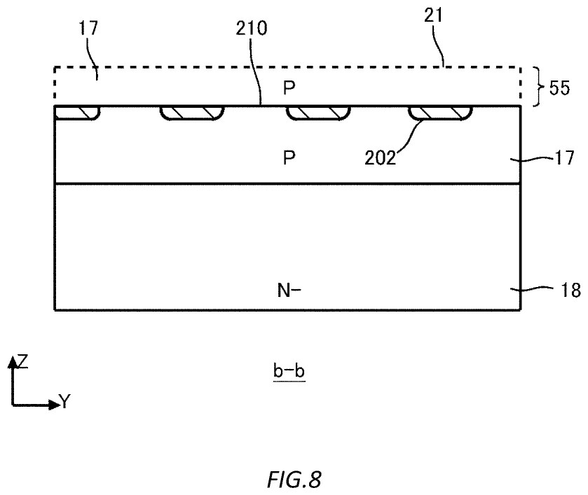

FIG. 8 shows an example of a YZ cross section taken along line b-b shown in FIG. 3A. FIG. 8 shows a cross section of the mesa portion 61 of the diode portion 80. The cross section passes through the trench contact portion 55. In FIG. 8, the anode region 17 projected on the cross section is indicated by a broken line.

The second bottom region 202 is discretely arranged along the Y axis direction. The second bottom region 202 is formed up to a predetermined depth from the bottom surface 210 of the trench contact portion 55. The second bottom region 202 may be formed more shallowly than the lower end of the anode region 17.

As an example of a manufacturing method of the semiconductor device 100, the groove structure of the trench contact portion 55 may be formed after the anode region 17 is formed on the upper surface 21 of the semiconductor substrate 10. Next, acceptor ions are implanted from the bottom surface 210 of the groove structure to form the second bottom region 202. The first bottom region 201 and the second bottom region 202 may be formed in the same step. The dose amount per unit area of the first bottom region 201 and the dose amount per unit area the second bottom region 202 may be the same.

According to this example, it is possible to suppress hole implantation from the second bottom region 202 while ensuring the contact property between the emitter electrode 52 and the anode region 17. With this configuration, the reverse recovery loss of the diode portion 80 can be reduced. Similarly to the trench contact portion 55 illustrated in FIG. 7B, the trench contact portion 55 of the mesa portion 61 may be formed more deeply.

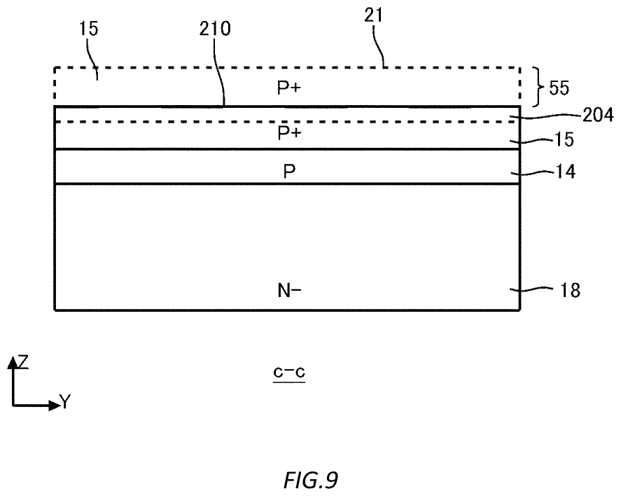

FIG. 9 shows an example of a YZ cross section taken along line c-c shown in FIG. 3A. FIG. 9 shows a cross section of the mesa portion 62 of the boundary portion 72. The cross section passes through the trench contact portion 55. In FIG. 9, the contact region 15 projected on the cross section is indicated by a broken line. As described above, in the mesa portion 62, the bottom of the trench contact portion 55 is not formed with a bottom region with a higher concentration than the contact region 15. Note that when the bottom region 204 is provided on the bottom surface of the trench contact portion 55 of the mesa portion 62, the bottom region 204 is indicated by a dotted line. Similarly to the trench contact portion 55 illustrated in FIG. 7B, the trench contact portion 55 of the mesa portion 62 may be formed more deeply.

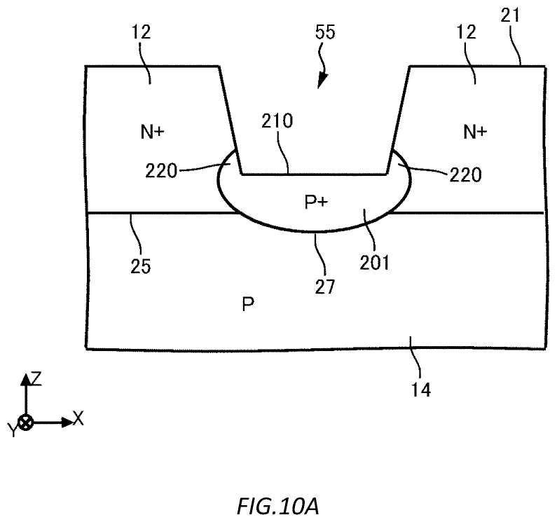

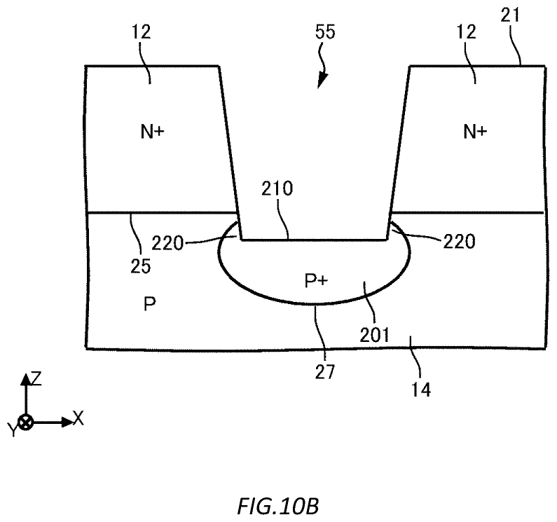

FIG. 10A shows an XZ cross section in the vicinity of the trench contact portion 55 of the mesa portion 60. In FIG. 10A, a groove structure is illustrated with a conductive material inside the trench contact portion 55 omitted.

The lower end (bottom surface 210) of each of the one or more trench contact portions may be arranged on the upper surface 21 side of the semiconductor substrate 10 relative to the lower end 25 of each of the one or more emitter regions 12. In another example, the bottom surface 210 of the trench contact portion 55 may be at the same depth position as the lower end of the emitter region 12, and may be arranged on the lower surface 23 side relative to the lower end 25.

The lower end 27 of the first bottom region 201 is arranged on the lower surface 23 side relative to the lower end 25 of the emitter region 12. The lower end 27 of the first bottom region 201 may be arranged inside the base region 14. The first bottom region 201 may have a portion 220 arranged on the upper surface 21 side relative to the bottom surface 210 of the trench contact portion 55.

FIG. 10B shows another example of the XZ cross section in the vicinity of the trench contact portion 55 of the mesa portion 60. The mesa portion 60 of this example is different from the mesa portion 60 illustrated in FIG. 10A in that the trench contact portion 55 penetrates the emitter region 12. That is, the bottom surface 210 of the trench contact portion 55 is formed more deeply than the lower end 25 of the emitter region 12. As the trench contact portion 55 is formed deeply, the bottom region 201 is also provided at a position deeper than that in the example of FIG. 10A. Other structures are similar to those in the example of FIG. 10A. The bottom region 201 may be separate from or in contact with the emitter region 12 in the Z axis direction.

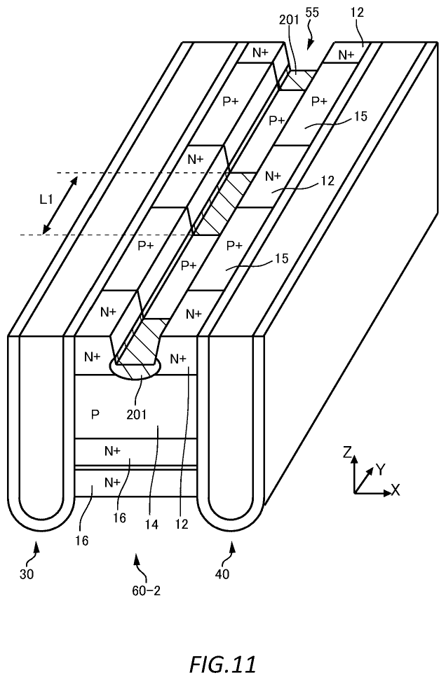

FIG. 11 illustrates a view showing another example of the mesa portion 60 of the transistor portion 70. The mesa portion 60 illustrated in FIG. 11 is referred to as a mesa portion The mesa portion 60-2 of this example is different from the mesa portion 60-1 in the structure of the first bottom region 201. Other points are similar to those of the mesa portion 60-1.

The mesa portion 60-2 has a plurality of first bottom regions 201 discretely arranged along the Y axis direction. The first bottom region 201 in this example may be arranged between two contact regions 15 adjacent to each other in the Y axis direction. The contact region 15 may be exposed between two first bottom regions 201 adjacent to each other on the bottom surface of the trench contact portion 55. The trench contact portion 55 of the mesa portion 60-2 may penetrate the emitter region 12 similarly to the trench contact portion 55 illustrated in FIG. 4B.

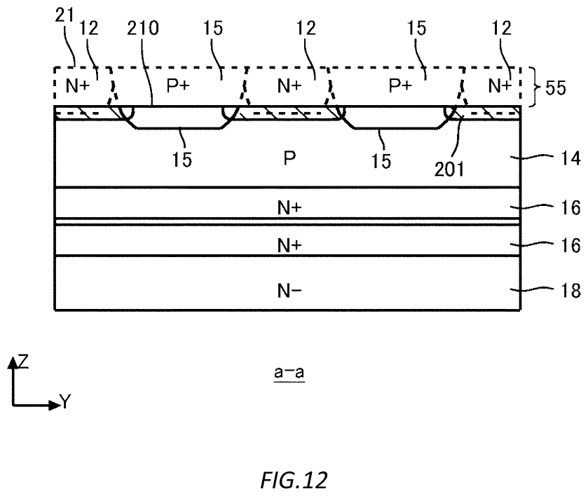

FIG. 12 illustrates a view showing a YZ cross section of the mesa portion 60-2. The first bottom region 201 of this example connects two contact regions 15 adjacent to each other in the Y axis direction. The first bottom region 201 may or may not have a portion overlapping the contact region 15. The trench contact portion 55 of the mesa portion 60-2 may penetrate the emitter region 12 similarly to the trench contact portion 55 illustrated in FIG. 7B.

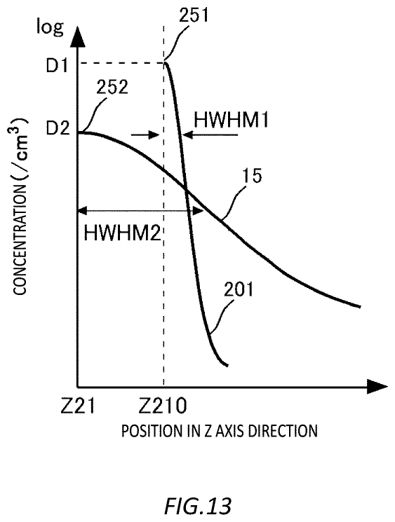

FIG. 13 illustrates a view showing an example of a doping concentration distribution taken along line f-f in FIG. 7A. Line f-f is a line passing through the contact region 15 and the first bottom region 201 of the mesa portion 60-1. A position of the upper surface 21 of the semiconductor substrate 10 in the depth direction is referred to as Z21, and a position of the bottom surface 210 of the trench contact portion 55 in the depth direction is referred to as Z210. In FIG. 13, the doping concentration distribution of the contact region 15 projected on the cross section of FIG. 7A is illustrated from the position Z21 to the position Z210 of the upper surface 21. In FIG. 13, the doping concentration distribution at a position deeper than the position Z210 is a distribution of a region below the trench contact portion 55.

A doping concentration D1 (/cm³) of the first bottom region 201 may be higher than a doping concentration D2 (/cm³) of the one or more contact regions 15. As the doping concentration D1 of the first bottom region 201, the maximum value of the doping concentration in the P type region between the position Z210 and the N type region (for example, the accumulation region 16 or the drift region 18) may be used. A doping concentration at the position Z210 may be set as the doping concentration D1 of the first bottom region 201.

The maximum value of the doping concentration in the P type region from the position Z21 to the position Z210 may be set as the doping concentration D2 of the contact region 15. A doping concentration at the position Z21 may be set as the doping concentration D2 of the contact region 15. The doping concentration D1 may be 2 times or more, 5 times or more, or 10 times or more the doping concentration D2. By increasing the doping concentration D1, latch-up is easily suppressed.

The first bottom region 201 may have a first concentration peak 251 in the depth direction of the doping concentration. Note that when the local maximum of the first concentration peak 251 is arranged at the position Z210, the first concentration peak 251 has a slope from the local maximum toward the lower surface 23 side and does not have a slope from the local maximum toward the upper surface 21 side.

The one or more contact regions 15 may have a second concentration peak 252 in the depth direction of the doping concentration. Note that when the local maximum of the second concentration peak 252 is arranged at the position Z21, the second concentration peak 252 has a slope from the local maximum toward the lower surface 23 side and does not have a slope from the local maximum toward the upper surface 21 side.

A half width at half maximum HWHM1 of the first concentration peak 251 may be smaller than a half width at half maximum HWHM2 of the second concentration peak 252. The half width at half maximum HWHM1 may be equal to or less than a half of the half width at half maximum HWHM2, may be equal to or less than ¼, or may be equal to or less than 1/10. With this configuration, the doping concentration D1 of the first concentration peak 251 can be increased without increasing the dose amount of the acceptor ions for forming the first bottom region 201. The half width at half maximum HWHM1 of the first concentration peak 251 can be controlled by the temperature or time of the heat treatment after implanting the acceptor ions to form the first bottom region 201. Although the doping concentration distribution of the first bottom region 201 has been described in FIG. 13, the second bottom region 202 and the third bottom region 203 may also have doping concentration distributions similar to that of the first bottom region 201.

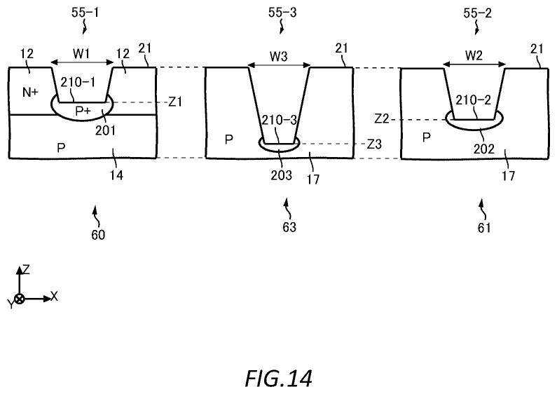

FIG. 14 illustrates a view showing a structure example of the trench contact portion 55 in each mesa portion. In this example, a trench contact portion 55-1, a trench contact portion 55-2, and a trench contact portion 55-3 in the mesa portion 60, the mesa portion 61, and the mesa portion 63 have different depths. The trench contact portion 55 in the mesa portion 62 may have the same structure as the trench contact portion 55-2 in the mesa portion 61.

A width of the trench contact portion 55-1 of the mesa portion 60 in the X axis direction is referred to as W1, and a depth thereof in the Z axis direction is referred to as Z1. A width of the trench contact portion 55-2 of the mesa portion 61 in the X axis direction is referred to as W2, and a depth thereof in the Z axis direction is referred to as Z2. A width of the trench contact portion of the mesa portion 63 in the X axis direction is referred to as W3, and a depth thereof in the Z axis direction is referred to as Z3. In this example, the width W1, the width W2, and the width W3 are the same. On the other hand, the depth Z2 is larger than the depth Z1. That is, the one or more trench contact portions 55-2 are provided up to below the one or more trench contact portions 55-1. By making the depth Z2 larger than the depth Z1, a width of a bottom surface 210-2 of the trench contact portion 55-2 can be made smaller than a width of a bottom surface 210-1 of the trench contact portion 55-1. Therefore, by making the width of the second bottom region 202, which is provided at the bottom of the trench contact portion 55-2, in the X axis direction smaller than the width of the first bottom region 201, which is provided at the bottom of the trench contact portion 55-1, in the X axis direction, implantation of holes in the mesa portion 61 can be suppressed.

Further, the depth Z3 may be larger than the depth Z2. That is, the one or more trench contact portions 55-3 are provided up to below the one or more trench contact portions 55-2. By making the depth Z3 larger than the depth Z2, a width of a bottom surface 210-3 of the trench contact portion 55-3 in the X axis direction can be made smaller than the width of the bottom surface 210-2 of the trench contact portion 55-2 in the X axis direction. Therefore, by making the third bottom region 203 provided at the bottom of the trench contact portion 55-3 smaller than the second bottom region 202 provided at the bottom of the trench contact portion 55-2, and implantation of holes in the mesa portion 63 can be suppressed. The depth Z3 may be 1.1 times or more, 1.2 times or more, or 1.5 times or more the depth Z2. The depth Z2 may be 1.1 times or more, 1.2 times or more, or 1.5 times or more the depth Z1. The trench contact portion 55 of the mesa portion 60 may penetrate the emitter region 12 similarly to the trench contact portion 55 illustrated in FIG. 4B.

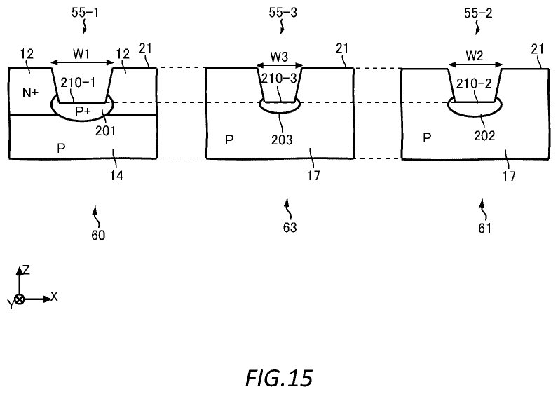

FIG. 15 illustrates a view showing a structure example of the trench contact portion 55 in each mesa portion. In this example, the trench contact portion 55-1, the trench contact portion 55-2, and the trench contact portion 55-3 in the mesa portion 60, the mesa portion 61, and the mesa portion 63 have different widths in the X axis direction. The trench contact portion 55 in the mesa portion 62 may have the same structure as the trench contact portion 55-2 in the mesa portion 61.

The width of the one or more trench contact portions 55-1 of the mesa portion 60 in the X axis direction is referred to as W1, the width of the one or more trench contact portions 55-2 of the mesa portion 61 in the X axis direction is referred to as W2, and the width of the one or more trench contact portions 55-3 of the mesa portion 63 in the X axis direction is referred to as W3.

The width of each trench contact portion 55 is a width at the upper surface 21 of the semiconductor substrate 10. Note that the depths of the trench contact portions 55 may be the same. The depths of the trench contact portions 55 may be different from each other. Each trench contact portion 55 may have the depth illustrated in FIG. 14.

The width W2 is smaller than the width W1. By making the width W2 smaller than the width W1, the width of the bottom surface 210-2 of the trench contact portion 55-2 can be made smaller than the width of the bottom surface 210-1 of the trench contact portion 55-1. Therefore, by making the width of the second bottom region 202, which is provided at the bottom of the trench contact portion 55-2, in the X axis direction smaller than the width of the first bottom region 201, which is provided at the bottom of the trench contact portion 55-1, in the X axis direction, implantation of holes in the mesa portion 61 can be suppressed.

Further, the width W3 may be smaller than the width W2. By making the width W3 smaller than the width W2, the width of the bottom surface 210-3 of the trench contact portion can be made smaller than the width of the bottom surface 210-2 of the trench contact portion Therefore, by making the width of the third bottom region 203, which is provided at the bottom of the trench contact portion 55-3, in the X axis direction smaller than the width of the second bottom region 202, which is provided at the bottom of the trench contact portion 55-2, in the X axis direction, implantation of holes in the mesa portion 63 can be suppressed. The width W1 may be 1.1 times or more, 1.2 times or more, or 1.5 times or more the width W2. The width W2 may be 1.1 times or more, 1.2 times or more, or 1.5 times or more the width W3. The trench contact portion 55 of the mesa portion 60 may penetrate the emitter region 12 similarly to the trench contact portion 55 illustrated in FIG. 4B.

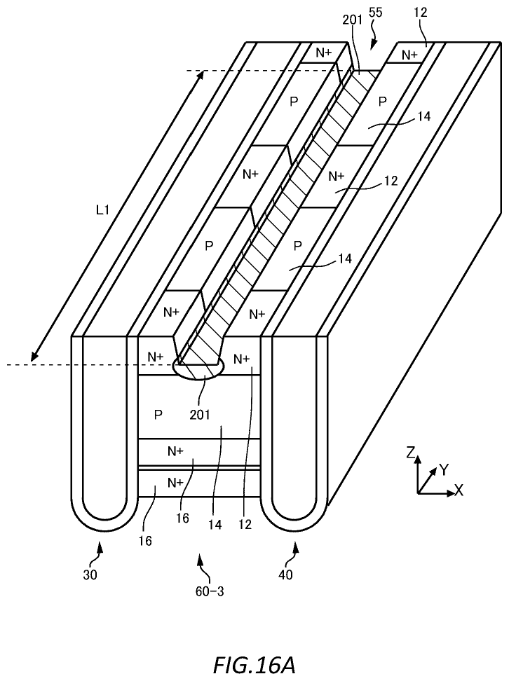

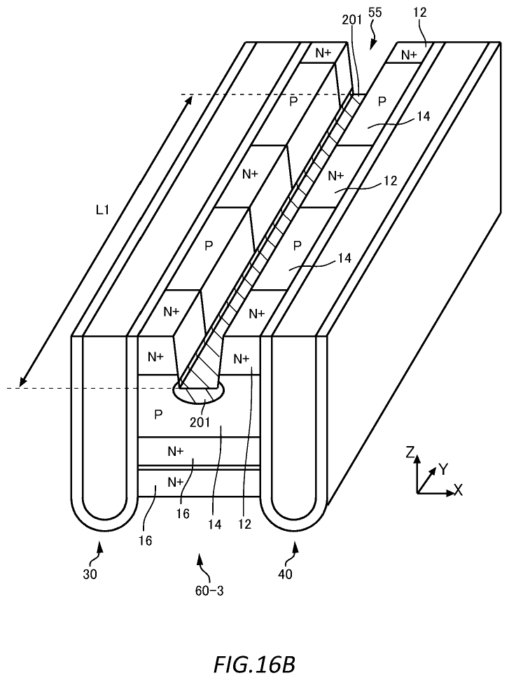

FIG. 16A illustrates a view showing another example of the mesa portion 60 of the transistor portion 70. The mesa portion 60 illustrated in FIG. 16A is referred to as a mesa portion 60-3. The mesa portion 60-3 of this example is different from the mesa portion 60-1 illustrated in FIG. 4A in that the base region 14 is provided instead of the contact region 15. Other points are similar to those of the mesa portion 60-1 illustrated in FIG. 4A. Also in this example, since holes can be extracted via the first bottom region 201 and the trench contact portion 55, latch-up of the transistor portion 70 can be suppressed.

FIG. 16B illustrates a view showing another example of the mesa portion 60-3. The mesa portion 60-3 of this example is different from the mesa portion 60-1 illustrated in FIG. 4B in that a base region 14 is provided instead of the contact region 15. Other points are similar to those of the mesa portion 60-1 illustrated in FIG. 4B. Also in this example, since holes can be extracted via the first bottom region 201 and the trench contact portion 55, latch-up of the transistor portion 70 can be suppressed.

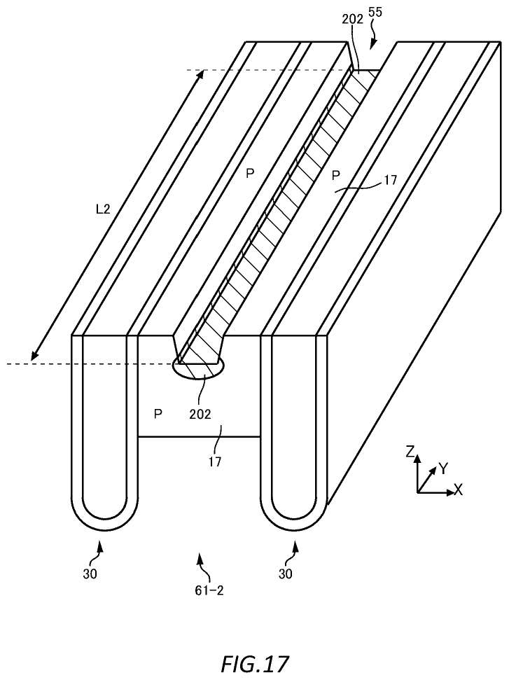

FIG. 17 illustrates a view showing another example of the mesa portion 61 of the diode portion 80. The mesa portion 61 illustrated in FIG. 17 is referred to as a mesa portion 61-2. The mesa portion 61-2 of this example is different from the mesa portion 61-1 in that one second bottom region 202 formed continuously is provided. Other points are similar to those of the mesa portion 61-1. The length L2 of the second bottom region 202 may be shorter than the length L1 of the first bottom region 201. In another example, the length L2 of the second bottom region 202 may be the same as the length L1 of the first bottom region 201.

Further, the doping concentration of the second bottom region 202 may be lower than the doping concentration of the first bottom region 201. In this case, even when the length L2 is the same as the length L1, the hole implantation amount of the mesa portion 61-2 can be suppressed. In another example, the doping concentration of the second bottom region 202 may be the same as the doping concentration of the first bottom region 201. Similarly to the trench contact portion 55 illustrated in FIG. 4B, the trench contact portion 55 of the mesa portion 61-2 may be formed more deeply.

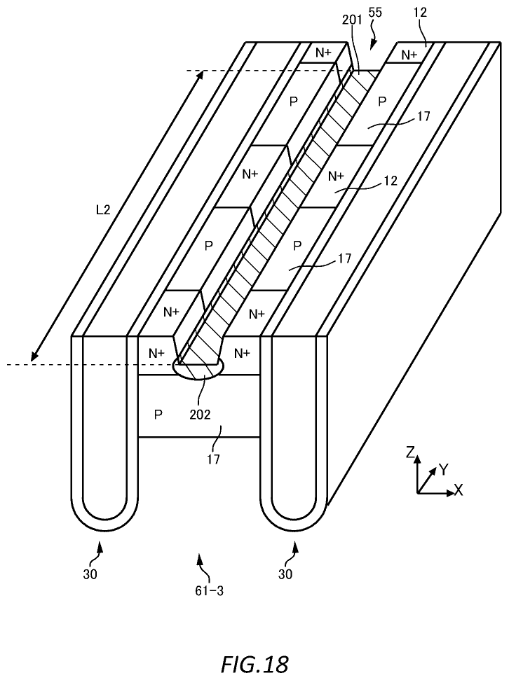

FIG. 18 illustrates a view showing another example of the mesa portion 61 of the diode portion 80. The mesa portion 61 illustrated in FIG. 18 is referred to as a mesa portion 61-3. The mesa portion 61-3 of this example is different from the mesa portion 61-1 or the mesa portion 61-2 in that the emitter region 12 and the anode region 17 are alternately exposed along the Y axis direction on the upper surface 21. Other points are similar to those of the mesa portion 61-1 or the mesa portion 61-2.

The transistor portion 70 may have the mesa portion 60 having any configuration described in FIGS. 1 to 18. The diode portion 80 may have the mesa portion 61 having any configuration described in FIGS. 1 to 18. The transistor portion 70 and the diode portion 80 may have any combination of the mesa portion 60 and the mesa portion 61 described above. Similarly to the trench contact portion 55 illustrated in FIG. 4B, the trench contact portion 55 of the mesa portion 61-3 may be formed more deeply.

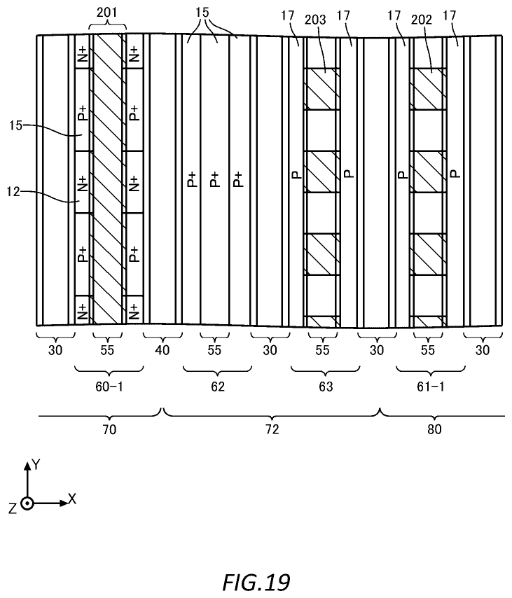

FIG. 19 illustrates a view showing an example of a combination of mesa portions in the semiconductor device 100. The transistor portion 70 of this example has the mesa portion 60-1. The diode portion 80 has the mesa portion 61-1. The structure of the mesa portion 63 is similar to that of the mesa portion 61-1.

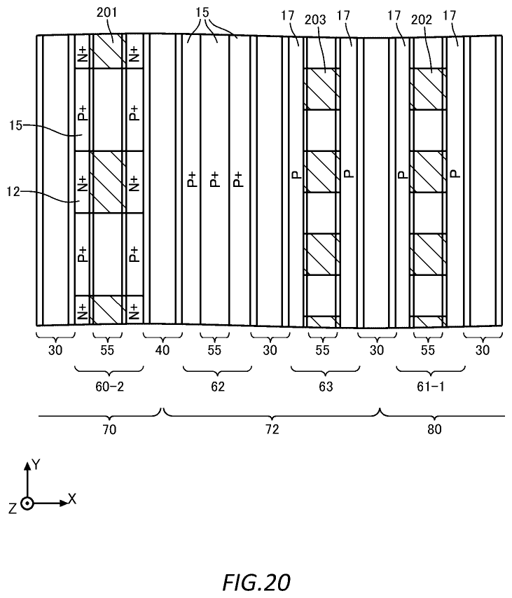

FIG. 20 illustrates a view showing another example of the combination of the mesa portions in the semiconductor device 100. The transistor portion 70 of this example has the mesa portion 60-2. The diode portion 80 has the mesa portion 61-1. The structure of the mesa portion 63 is similar to that of the mesa portion 61-1.

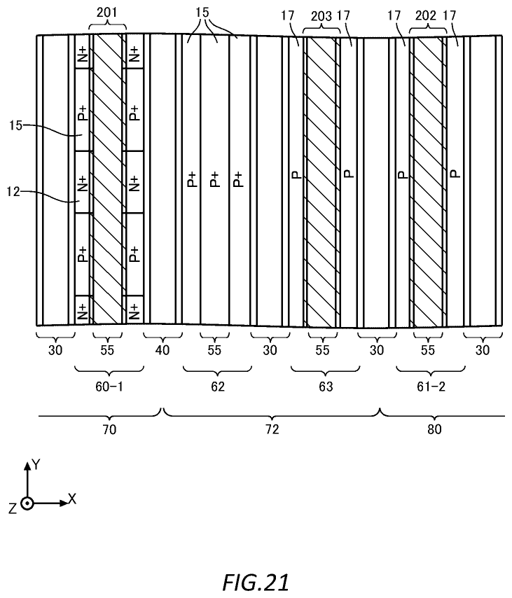

FIG. 21 illustrates a view showing another example of the combination of the mesa portions in the semiconductor device 100. The transistor portion 70 of this example has the mesa portion 60-1. The diode portion 80 has the mesa portion 61-2. The structure of the mesa portion 63 is similar to that of the mesa portion 61-2.

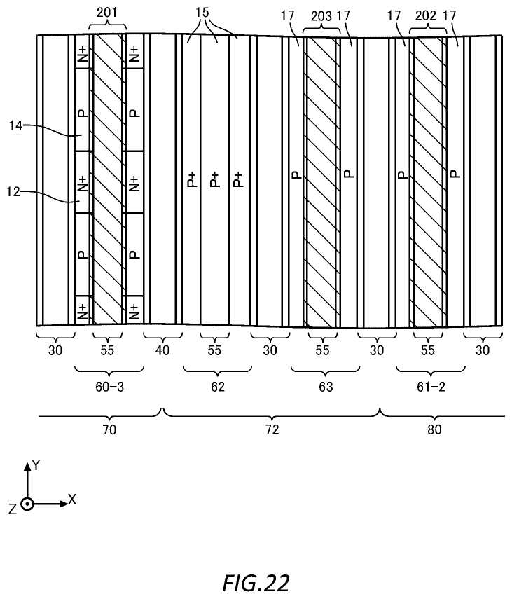

FIG. 22 illustrates a view showing another example of the combination of the mesa portions in the semiconductor device 100. The transistor portion 70 of this example has the mesa portion 60-3. The diode portion 80 has the mesa portion 61-2. The structure of the mesa portion 63 is similar to that of the mesa portion 61-2.

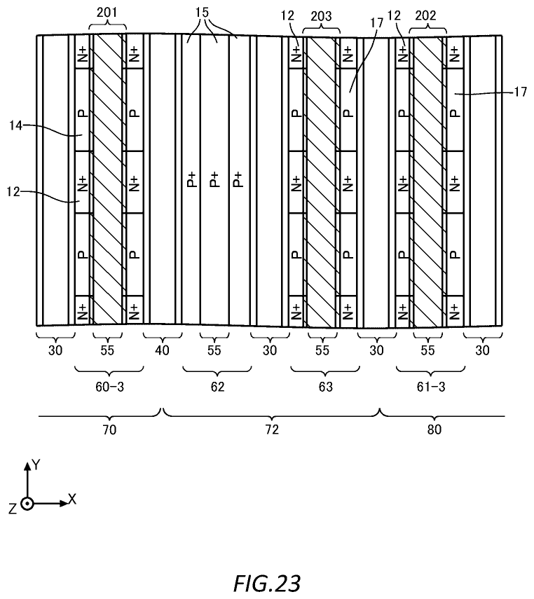

FIG. 23 illustrates a view showing another example of the combination of the mesa portions in the semiconductor device 100. The transistor portion 70 of this example has the mesa portion 60-3. The diode portion 80 has the mesa portion 61-3. The structure of the mesa portion 63 is similar to that of the mesa portion 61-3.

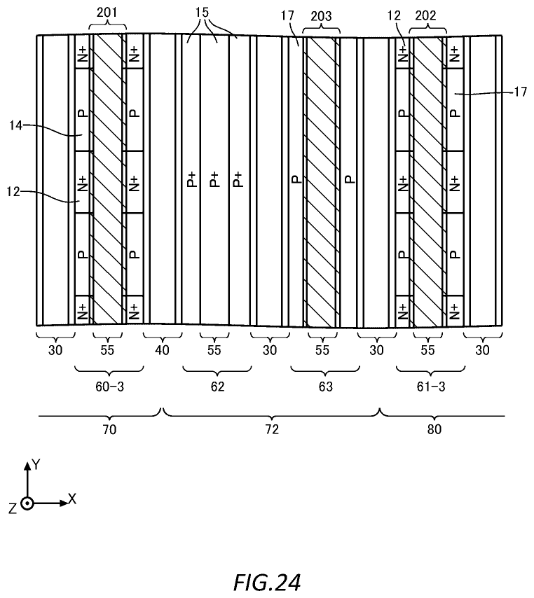

FIG. 24 illustrates a view showing another example of the combination of the mesa portions in the semiconductor device 100. The transistor portion 70 of this example has the mesa portion 60-3. The diode portion 80 has the mesa portion 61-3. The structure of the mesa portion 63 is similar to that of the mesa portion 61-2.

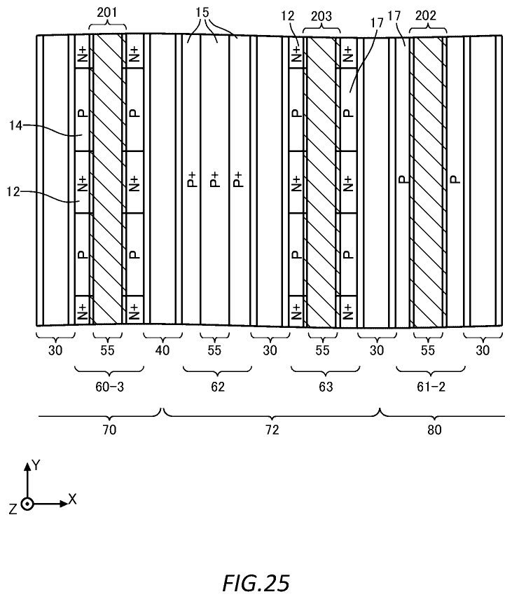

FIG. 25 illustrates a view showing another example of the combination of the mesa portions in the semiconductor device 100. The transistor portion 70 of this example has the mesa portion 60-3. The diode portion 80 has the mesa portion 61-2. The structure of the mesa portion 63 is similar to that of the mesa portion 61-3. Note that the combination of the mesa portions in the semiconductor device 100 is not limited to the examples of FIGS. 19 to 25.

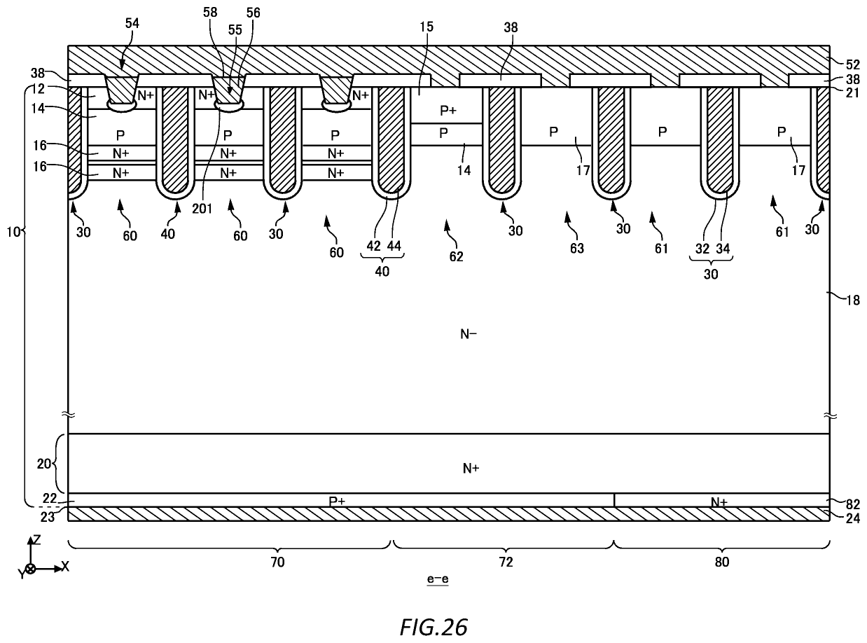

FIG. 26 is a cross section e-e showing another configuration example of the semiconductor device 100. The semiconductor device 100 of this example is different from the semiconductor device 100 described in FIGS. 1 to 25 in the structures of the boundary portion 72 and the diode portion 80. Other structures are similar to those of any of the semiconductor devices 100 described in FIGS. 1 to 25.

The diode portion 80 of this example does not have the trench contact portion 55 and the second bottom region 202. Other structures are similar to those of any of the diode portions 80 described in FIGS. 1 to 25. The boundary portion 72 of this example does not have the trench contact portion 55 and the third bottom region 203. Other structures are similar to those of any of the boundary portions 72 described in FIGS. 1 to 25. Similarly to the trench contact portion 55 illustrated in FIG. 3B, the trench contact portion 55 of this example may be formed more deeply.

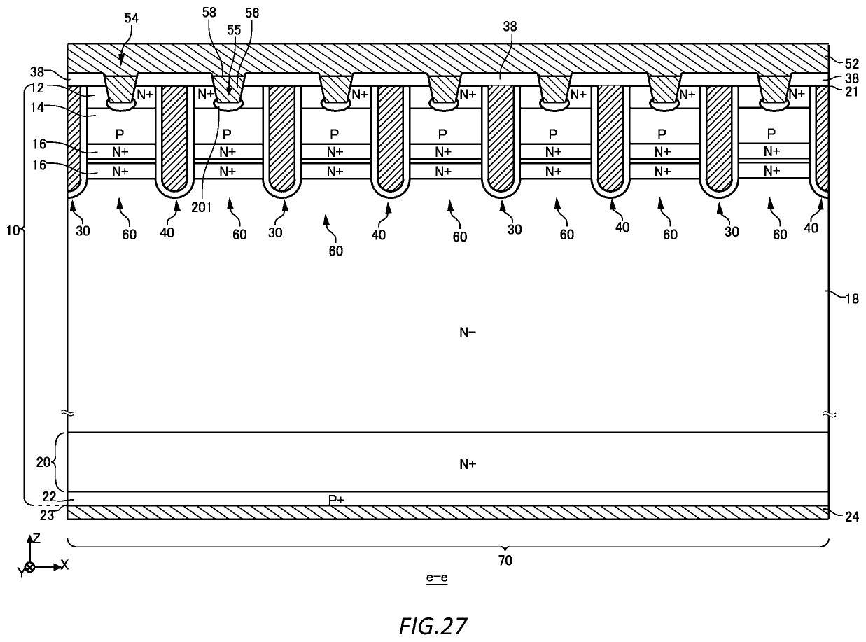

FIG. 27 is a cross section e-e showing another configuration example of the semiconductor device 100. The semiconductor device 100 of this example does not include the boundary portion 72 and the diode portion 80. Other points are similar to those of any of the semiconductor devices 100 described in FIGS. 1 to 25. Similarly to the trench contact portion 55 illustrated in FIG. 3B, the trench contact portion 55 of this example may be formed more deeply.

The transistor portion 70 in the examples of FIGS. 26 and 27 has the doping concentration distribution described in FIG. 13. By providing the first bottom region 201 having a higher concentration than the contact region 15, latch-up can be easily suppressed. The half width at half maximum HWHM1 of the first concentration peak 251 may be smaller than the half width at half maximum HWHM2 of the second concentration peak 252.

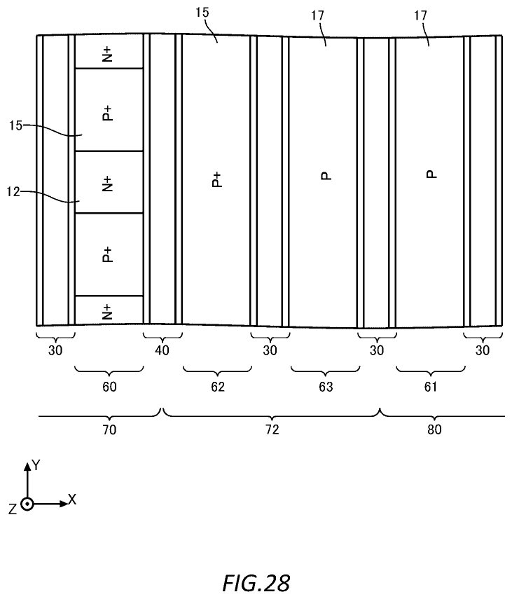

FIG. 28 illustrates a top view showing another configuration example of the semiconductor device 100. In each mesa portion of this example, the trench contact portion 55 and the bottom region are not provided. Other structures are similar to those in any of the examples described in FIGS. 1 to 27.

In the example of FIG. 28, in the mesa portion 60, the emitter regions 12 and the contact regions 15 are alternately arranged along the Y axis direction on the upper surface 21. In the mesa portion 61 and the mesa portion 63, the anode region 17 is provided on the upper surface 21. The anode region 17 may have a lower doping concentration than that of the base region 14, and may have the same doping concentration as that of the base region 14. The mesa portion 62 is provided with the contact region 15 on the upper surface 21.

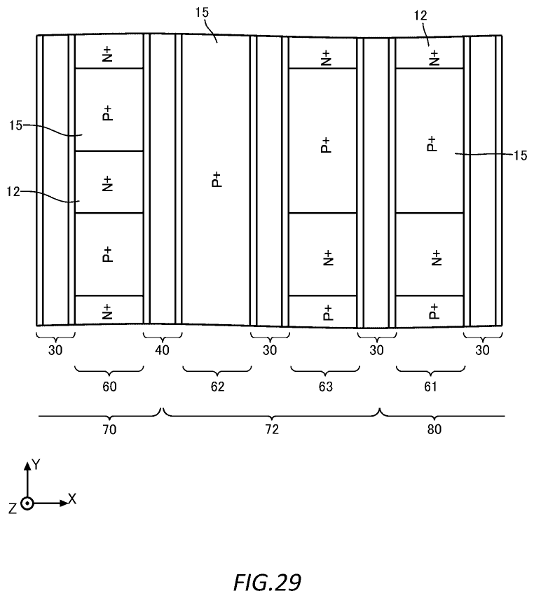

FIG. 29 illustrates a top view showing another configuration example of the semiconductor device 100. In this example, the structures of the mesa portion 61 and the mesa portion 63 are different from those in the example of FIG. 28. Other points are similar to those in the example of FIG. 28. The emitter regions 12 and the contact regions 15 are alternately arranged in the mesa portion 61 and the mesa portion 63 along the Y axis direction.

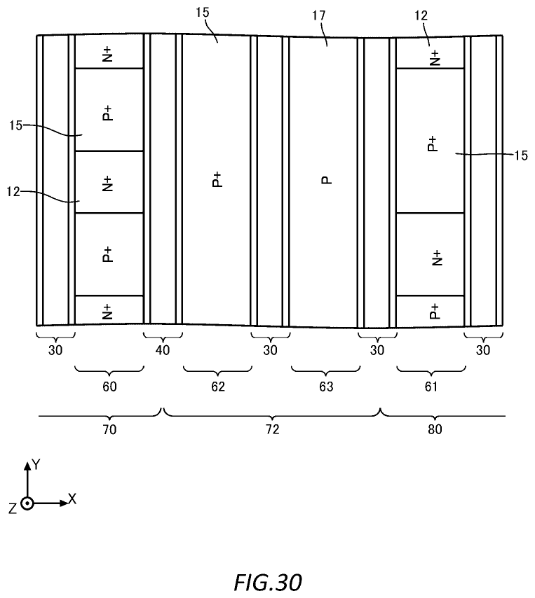

FIG. 30 illustrates a top view showing another configuration example of the semiconductor device 100. In this example, the structure of the mesa portion 61 is different from that in the example of FIG. 28. Other points are similar to those in the example of FIG. 28. The emitter regions 12 and the contact regions 15 are alternately arranged in the mesa portion 61 along the Y axis direction.

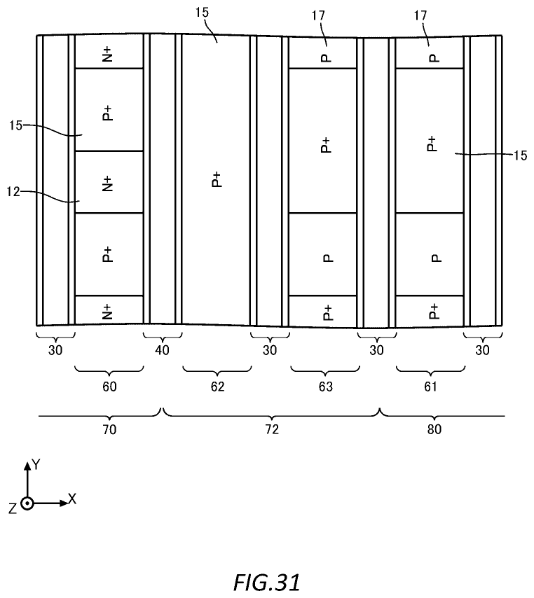

FIG. 31 illustrates a top view showing another configuration example of the semiconductor device 100. In this example, the structures of the mesa portion 61 and the mesa portion 63 are different from those in the example of FIG. 28. Other points are similar to those in the example of FIG. 28. The anode region 17 and the contact region 15 are alternately arranged in the mesa portion 61 and the mesa portion 63 along the Y axis direction.

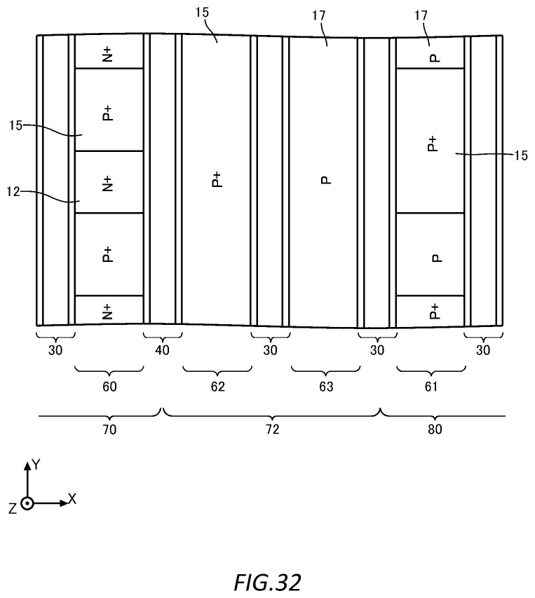

FIG. 32 illustrates a top view showing another configuration example of the semiconductor device 100. In this example, the structure of the mesa portion 61 is different from that in the example of FIG. 28. Other points are similar to those in the example of FIG. 28. The anode region 17 and the contact region 15 are alternately arranged in the mesa portion 61 along the Y axis direction.

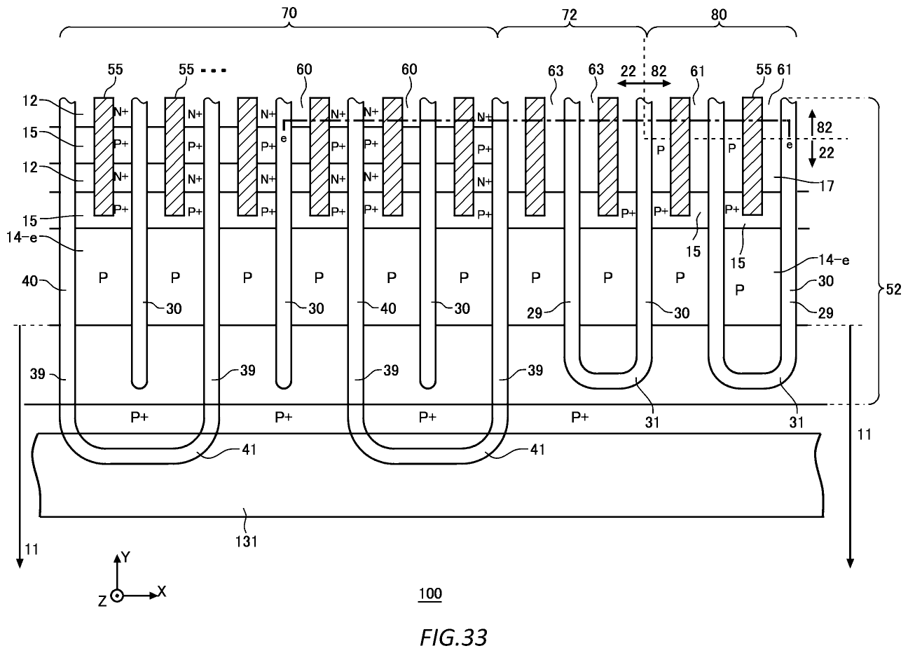

FIG. 33 illustrates a view showing another configuration example of the semiconductor device 100. The semiconductor device 100 described with reference to FIGS. 1 to 32 has the mesa portion 62, but the semiconductor device 100 of this example does not have the mesa portion 62.

The semiconductor device 100 of this example may have the mesa portion 63 instead of the mesa portion 62. The boundary portion 72 may continuously have one or more mesa portions 63 between the transistor portion 70 and the diode portion 80. The structure of the semiconductor device 100 of this example is similar to that of the semiconductor device 100 according to any of aspects described with reference to FIGS. 1 to 32 except that the mesa portion 62 is not provided. As an example, FIG. 33 shows an example in which the mesa portion 62 is not provided in the structure illustrated in FIG. 2.

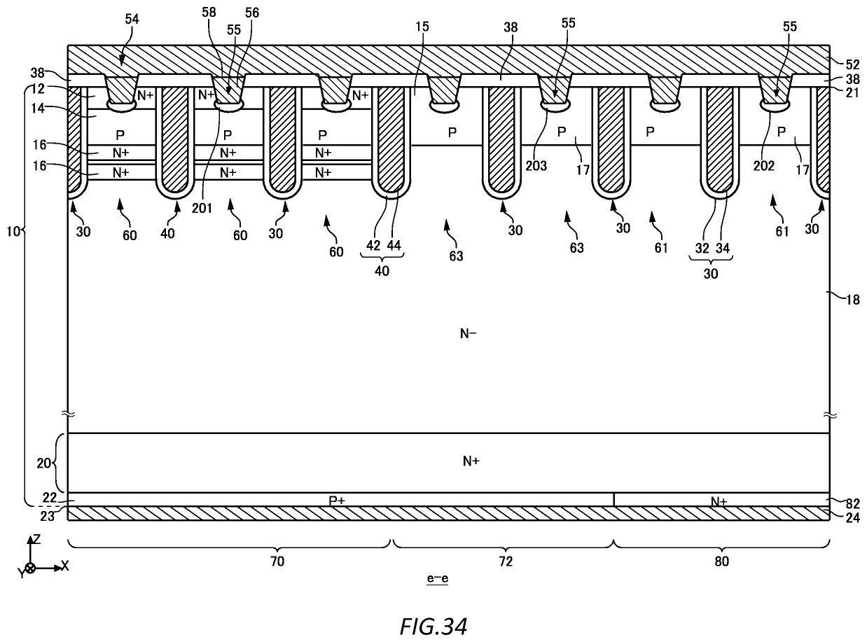

FIG. 34 illustrates a view showing an example of a cross section e-e in FIG. 33. The semiconductor device 100 of this example is different from the semiconductor device 100 illustrated in FIG. 3A in that the mesa portion 63 is provided instead of the mesa portion 62. Other structures are similar to those of the semiconductor device 100 illustrated in FIG. 3A.

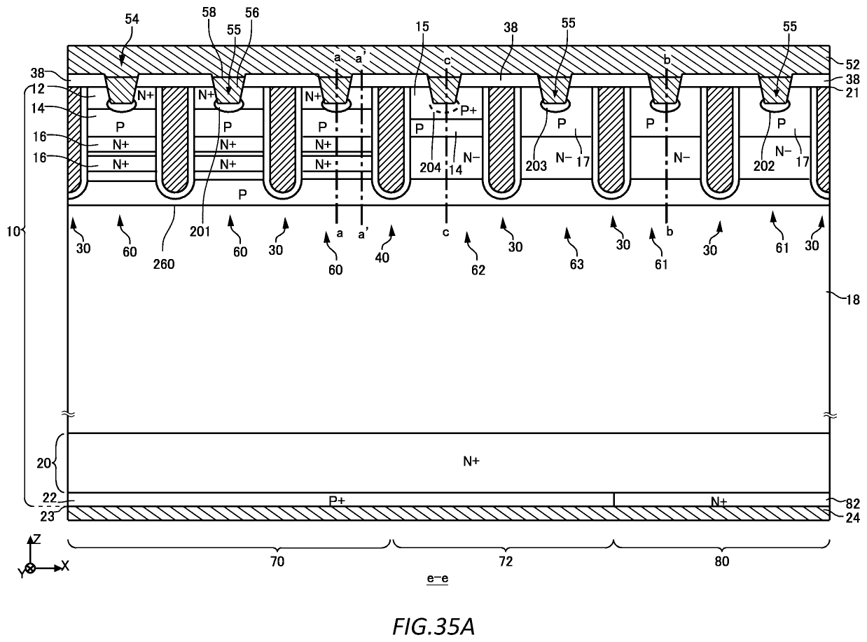

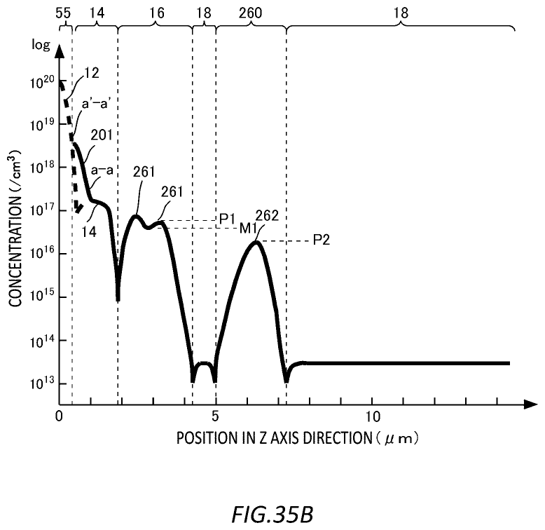

FIG. 35A illustrates a view showing another configuration example of the semiconductor device 100. The semiconductor device 100 of this example further includes a trench bottom region 260 with respect to the configuration of any of the semiconductor devices 100 described in FIGS. 1 to 34. The trench bottom region 260 may be applied to the semiconductor device 100 of any aspect described in FIGS. 1 to 34. FIG. 35A shows an example in which the trench bottom region 260 is added to the configuration of the semiconductor device 100 illustrated in FIG. 3A.

The trench bottom region 260 is a P type region provided in contact with the lower end of the trench portion. The doping concentration of the trench bottom region 260 may be equal to or less than the doping concentration of the base region 14. The doping concentration of the trench bottom region 260 of this example is lower than the doping concentration of the base region 14.

The trench bottom region 260 is continuously provided so as to be in contact with lower ends of two or more trench portions in the X axis direction. That is, the trench bottom region 260 is provided so as to cover the mesa portion between the trench portions. The trench bottom region 260 may cover a plurality of mesa portions.

The trench bottom region 260 may be in contact with the lower ends of two or more trench portions in each transistor portion 70. Further, the trench bottom region 260 may be in contact with the lower ends of two or more gate trench portions 40 in each transistor portion 70. The trench bottom region 260 may be in contact with the lower ends of all the trench portions in at least one transistor portion 70. Further, the trench bottom region 260 may be in contact with the lower ends of all the gate trench portions 40 in at least one transistor portion 70.

The trench bottom region 260 may be in contact with the lower ends of two or more trench portions in each diode portion 80. The trench bottom region 260 may be in contact with the lower ends of all the trench portions in the at least one diode portion 80.

The trench bottom region 260 may be in contact with the lower ends of two or more trench portions at the boundary portion 72. The trench bottom region 260 may be in contact with the lower ends of all the trench portions of the boundary portion 72. In the example of FIG. 35A, the trench bottom region 260 is provided in all the mesa portions of the semiconductor device 100.

The trench bottom region 260 is arranged between the upper surface side P type region (that is, the base region 14, the anode region 17, or the contact region 15) arranged on the upper surface 21 side of the semiconductor substrate 10 and the drift region 18. The trench bottom region 260 may be arranged away from the upper surface side P type region. The N type region (in this example, at least one of the accumulation region 16 and the drift region 18) is provided between the trench bottom region 260 and the upper surface side P type region.

The trench bottom region 260 is provided to extend in the Y axis direction. The length of the trench bottom region 260 in the Y axis direction is shorter than the length of the trench portion in the Y axis direction. Further, the length of the trench bottom region 260 in the Y axis direction may be 50% or more, 70% or more, or 90% or more of the length of the trench portion in the Y axis direction.

By providing the trench bottom region 260, it is possible to suppress an increase in potential in the vicinity of the lower end of the trench portion at the time of turn-on of the semiconductor device 100. Therefore, the slope (dv/dt) of the waveform of the emitter-collector voltage at the time of turn-on can be reduced, and the noise of the voltage or current waveform at the time of switching can be reduced.

The potential of the trench bottom region 260 is different from the potential of the emitter electrode 52. As described above, the trench bottom region 260 is arranged away from the base region 14 connected to the emitter electrode 52 in the Z axis direction. Further, the trench bottom region 260 is arranged away from the well region 11 connected to the emitter electrode 52 in the top view. The N type region such as the drift region 18 may be provided between the well region 11 and the trench bottom region 260. The trench bottom region 260 of this example is a P type region having a doping concentration lower than that of the well region 11.

FIG. 35B illustrates a view showing an example of the doping concentration distribution of a cross section a-a and a cross section a′-a′ in FIG. 35A. A horizontal axis in FIG. 35B indicates a position in the Z axis direction with the upper surface 21 of the semiconductor substrate 10 as a reference position (0 μm). In FIG. 35B, the doping concentration distribution in the cross section a-a is indicated by a solid line, and the doping concentration distribution in the cross section a′-a′ is indicated by a dotted line. The first bottom region portion 201 and the base region 14 are provided near the bottom surface of the trench contact portion 55 in the cross section a-a. The emitter region 12 and the base region 14 are provided near the upper surface 21 of the semiconductor substrate 10 in the cross section a′-a′. The accumulation region 16 of this example has two peaks 261 in the doping concentration distribution. The doping concentration distribution of the trench bottom region 260 may have a peak 262. A peak value P2 of the doping concentration of the trench bottom region 260 may be smaller than a minimum value P1 of the two peak values of the doping concentration of the accumulation region 16. The peak value P2 of the doping concentration of the trench bottom region 260 may be smaller than a local minimum value M1 between the two peaks of the doping concentration of the accumulation region 16. Alternatively, the accumulation region 16 of this example may have a kink shape instead of the local minimum value M1 between the two peaks 261 of the doping concentration distribution.

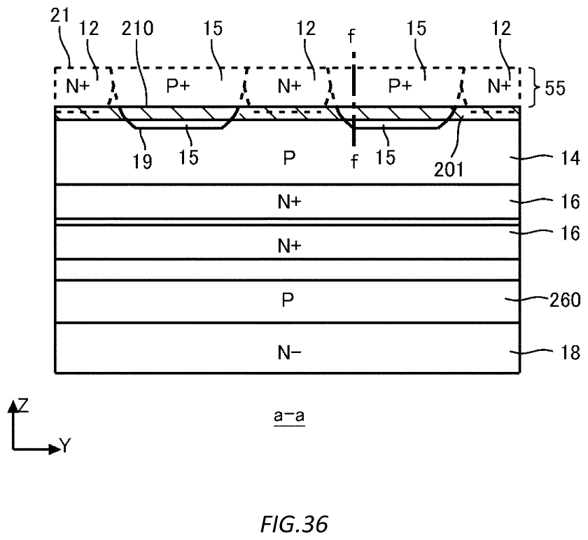

FIG. 36 shows an example in which the trench bottom region 260 is added to the structure of the mesa portion 60 illustrated in FIG. 7A. The trench bottom region 260 extends in the Y axis direction. The trench bottom region 260 may be provided in a range wider than that of the first bottom region 201 in the Y axis direction, may be provided in the same range as that of the first bottom region 201, or may be provided in a range narrower than that of the first bottom region 201.

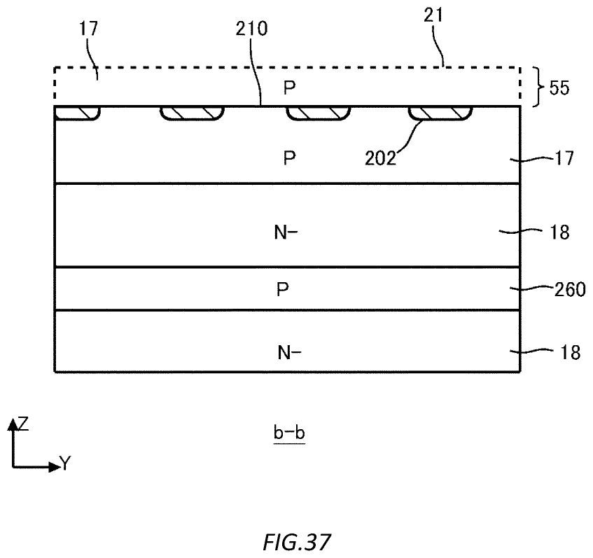

FIG. 37 shows an example in which the trench bottom region 260 is added to the structure of the mesa portion 61 illustrated in FIG. 8. The trench bottom region 260 extends in the Y axis direction. The trench bottom region 260 in the mesa portion 61 may have the same structure as the trench bottom region 260 in the mesa portion 60. In another example, the trench bottom regions 260 may be discretely arranged in the Y axis direction similarly to the first bottom regions 201. At least a part of the trench bottom region 260 may overlap the first bottom region 201 in the top view. At least a part of the trench bottom region 260 may not overlap the first bottom region 201 in the top view.

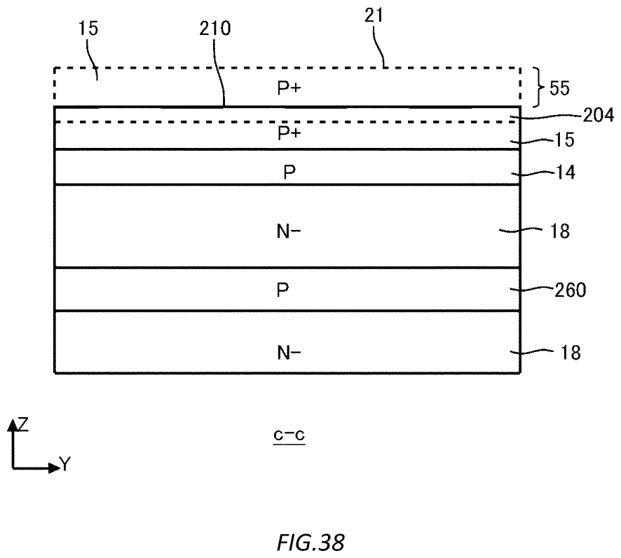

FIG. 38 shows an example in which the trench bottom region 260 is added to the structure of the mesa portion 62 illustrated in FIG. 9. The trench bottom region 260 extends in the Y axis direction. The trench bottom region 260 in the mesa portion 62 may have the same structure as the trench bottom region 260 in the mesa portion 60.

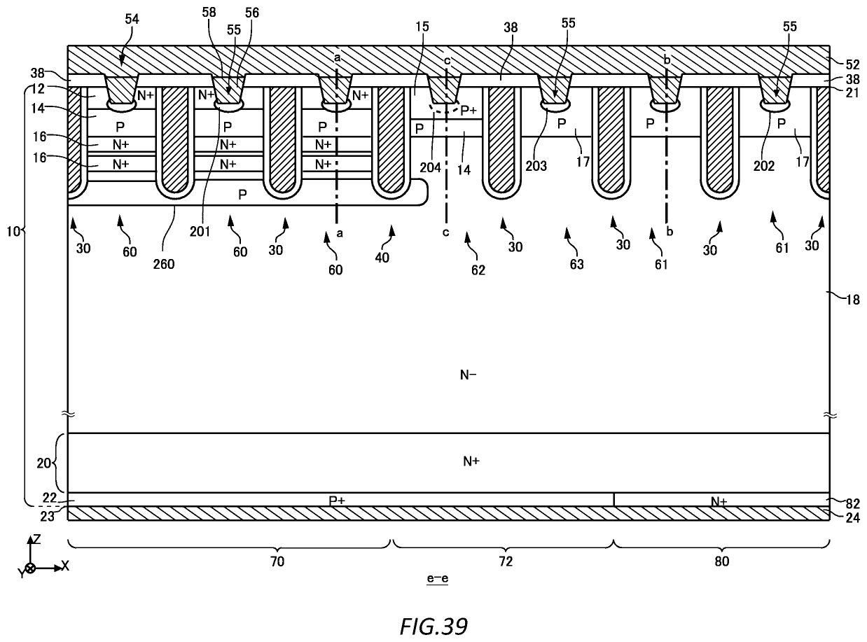

FIG. 39 illustrates a view showing another configuration example of the semiconductor device 100. The semiconductor device 100 of this example is different from the semiconductor device 100 illustrated in FIG. 35A in a range in which the trench bottom region 260 is provided. Other structures are similar to those in the example of FIG. 35A. The trench bottom region 260 of this example may also be applied to the semiconductor device 100 of any aspect described in FIGS. 1 to 34.

The trench bottom region 260 of this example is provided in at least a part of a region of the transistor portion 70. In the example of FIG. 39, the trench bottom region 260 is provided over the entire transistor portion 70 in the X axis direction.

The trench bottom region 260 may be provided in at least a part of the boundary portion 72. The trench bottom region 260 of this example is provided in at least a part of the mesa portion closest to the transistor portion 70 in the mesa portion of the boundary portion 72. The trench bottom region 260 may extend from the transistor portion 70 to the middle of the boundary portion 72.

The trench bottom region 260 may be provided or may not be provided in at least a part of the diode portion 80. In this example, the diode portion 80 is not provided with the trench bottom region 260. The cross section a-a in FIG. 39 is similar to that in the example illustrated in FIG. 36. The cross section b-b and the cross section c-c in FIG. 39 are similar to those in any of the examples described in FIGS. 1 to 34.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device comprising:
a semiconductor substrate which has an upper surface and a lower surface and is provided with a drift region of a first conductivity type;
a transistor portion which is provided on the semiconductor substrate; and
a diode portion which is provided on the semiconductor substrate, wherein
each of the transistor portion and the diode portion has one or more trench contact portions provided from the upper surface of the semiconductor substrate in a depth direction of the semiconductor substrate and extending on the upper surface of the semiconductor substrate in an extending direction,
the transistor portion has a first bottom region of a second conductivity type provided in contact with a bottom of any one of the one or more trench contact portions,
the diode portion has a second bottom region of the second conductivity type provided in contact with a bottom of any one of the one or more trench contact portions, and
a length of the first bottom region in the extending direction is larger than a length of the second bottom region in the extending direction.

2. The semiconductor device according to claim 1, wherein
a plurality of the second bottom regions is discretely arranged in the diode portion along the extending direction.

3. The semiconductor device according to claim 1, further comprising:
a boundary portion which is provided between the transistor portion and the diode portion and includes the one or more trench contact portions, wherein
the boundary portion has a third bottom region of the second conductivity type provided in contact with a bottom of any one of the one or more trench contact portions, and
the length of the first bottom region in the extending direction is larger than a length of the third bottom region in the extending direction.

4. The semiconductor device according to claim 3, wherein
the length of the second bottom region in the extending direction is the same as the length of the third bottom region in the extending direction.

5. The semiconductor device according to claim 1, wherein
the transistor portion includes:
one or more emitter regions of the first conductivity type which are provided in contact with the upper surface of the semiconductor substrate and have a higher doping concentration than the drift region;
one or more base regions of the second conductivity type which are provided between the one or more emitter regions and the drift region;
one or more contact regions of the second conductivity type which are provided in contact with the upper surface of the semiconductor substrate, are connected to the one or more base regions and have a higher doping concentration than the one or more base regions; and
one or more gate trench portions which are in contact with the one or more emitter regions and the one or more base regions and are provided from the upper surface toward the lower surface, and
the extending direction is a longitudinal direction in which the one or more gate trench portions extend.

6. The semiconductor device according to claim 5, wherein
the one or more contact regions are arranged alternately with the one or more emitter regions in the extending direction, and
the first bottom region connects two of the one or more contact regions arranged away from each other in the extending direction.

7. The semiconductor device according to claim 6, wherein
a partial region of the first bottom region is provided on a side of the upper surface of the semiconductor substrate relative to a lower end of each of the one or more contact regions.

8. The semiconductor device according to claim 7, wherein
a doping concentration of the first bottom region is higher than a doping concentration of the one or more contact regions.

9. The semiconductor device according to claim 8, wherein
the first bottom region has a first concentration peak of a doping concentration in a depth direction,
the one or more contact regions have a second concentration peak of the doping concentration in the depth direction, and
a half width at half maximum of the first concentration peak is smaller than a half width at half maximum of the second concentration peak.

10. The semiconductor device according to claim 5, wherein
a lower end of each of the one or more trench contact portions is arranged on a side of the upper surface of the semiconductor substrate relative to a lower end of each of the one or more emitter regions.

11. The semiconductor device according to claim 1, wherein
the one or more trench contact portions of the diode portion are provided up to below the one or more trench contact portions of the transistor portion.

12. The semiconductor device according to claim 1, wherein
the one or more trench contact portions of the diode portion have a smaller width on the upper surface of the semiconductor substrate than the one or more trench contact portions of the transistor portion.

13. The semiconductor device according to claim 3, wherein
the one or more trench contact portions of the boundary portion are provided up to below both the one or more trench contact portions of the diode portion and the one or more trench contact portions of the transistor portion.

14. The semiconductor device according to claim 3, wherein
the one or more trench contact portions of the boundary portion have a smaller width on the upper surface of the semiconductor substrate than both the one or more trench contact portions of the diode portion and the one or more trench contact portions of the transistor portion.

15. The semiconductor device according to claim 5, wherein
the diode portion has an anode region of the second conductivity type provided between the drift region and the upper surface of the semiconductor substrate, and
a doping concentration of the anode region is lower than a doping concentration of the one or more base regions.

16. The semiconductor device according to claim 5, wherein
the transistor portion further has a plurality of accumulation regions which is provided in the depth direction between the one or more base regions and the drift region and which has a higher doping concentration than the drift region.

17. A semiconductor device comprising:
a semiconductor substrate which has an upper surface and a lower surface and is provided with a drift region of a first conductivity type; and
a transistor portion which is provided on the semiconductor substrate, wherein
the transistor portion includes:
one or more trench contact portions which are provided from the upper surface of the semiconductor substrate in a depth direction of the semiconductor substrate;
a first bottom region of a second conductivity type which is provided in contact with a bottom of any one of the one or more trench contact portions;
an emitter region of the first conductivity type which is provided in contact with the upper surface of the semiconductor substrate and has a higher doping concentration than the drift region;
a base region of the second conductivity type which is provided between the emitter region and the drift region; and
a contact region of the second conductivity type which is provided in contact with the upper surface of the semiconductor substrate, is connected to the base region and has a higher doping concentration than the base region, and
a doping concentration of the first bottom region is higher than a doping concentration of the contact region.

18. The semiconductor device according to claim 17, wherein
the first bottom region has a first concentration peak of a doping concentration in a depth direction,
the contact region has a second concentration peak of the doping concentration in the depth direction, and
a half width at half maximum of the first concentration peak is smaller than a half width at half maximum of the second concentration peak.

19. The semiconductor device according to claim 17, wherein
the one or more trench contact portions extend on the upper surface of the semiconductor substrate in an extending direction, and
a plurality of the first bottom regions is discretely arranged along the extending direction.

20. The semiconductor device according to claim 17, wherein
the bottom of each of the one or more trench contact portions is arranged on a side of the upper surface of the semiconductor substrate relative to both a lower end of the emitter region and a lower end of the contact region.

21. The semiconductor device according to claim 17, wherein
the bottom of each of the one or more trench contact portions is arranged on a side of the upper surface of the semiconductor substrate relative to a lower end of the emitter region, and
a lower end of the first bottom region is arranged on a side of the lower surface of the semiconductor substrate relative to the lower end of the emitter region.

22. The semiconductor device according to claim 17, wherein
the one or more trench contact portions extend on the upper surface of the semiconductor substrate in an extending direction, and
a length of the first bottom region in the extending direction is smaller than a length of the one or more trench contact portions in the extending direction.

23. The semiconductor device according to claim 17, further comprising:
a diode portion which is provided on the semiconductor substrate, wherein
each of the transistor portion and the diode portion has one or more trench contact portions provided from the upper surface of the semiconductor substrate in a depth direction of the semiconductor substrate and extending on the upper surface of the semiconductor substrate in an extending direction,
the diode portion has a second bottom region of the second conductivity type provided in contact with a bottom of any one of the one or more trench contact portions, and
a length of the first bottom region in the extending direction is smaller than a length of the second bottom region in the extending direction.
